(19) United States
(12) Patent Application Publication
(10) Pub. No.: US 2006/0236917 A1
(43) Pub. Date: Oct. 26, 2006

(54) METHOD OF FORMING CONDUCTIVE FILM AND METHOD OF MANUFACTURING ELECTRONIC APPARATUS

(76) Inventor: Atsushi DENDA, Suwa (JP)

Correspondence Address: HARNESS, DICKEY & PIERCE, P.L.C., P.O. BOX 828, BLOOMFIELD HILLS, MI, 48303, US

(21) Appl. No.: 11/379,302

(22) Filed: Apr. 19, 2006

(30) Foreign Application Priority Data
Apr. 21, 2005 (JP) 2005-123193

(51) Int. Cl. C30B 19/00

(52) U.S. Cl. 117/60

(57) ABSTRACT

A method of forming a conductive film includes disposing liquid material containing particulate materials on a substrate, and baking the liquid material on the substrate through light-irradiation using a flash lamp so as to form a conductive film.

### BACKGROUND

1. Technical Field

The present invention relates to a method of forming a conductive film and to a method of manufacturing an electronic apparatus.

2. Related Art

A conductive film (optically-transparent conductive film) is used in an electrode of an electro-optical device, an electrode of a touch panel, an electromagnetic wave shielding material, or the like. As a representative example, an indium tin oxide (ITO) doped with tin is known. In general, an ITO film is generally formed by using an evaporation method or sputtering method. However, in order to remarkably reduce manufacturing cost and to collectively form a film on a large area, a method of forming an ITO film using a liquid phase method has been examined.

For example, JP-A-2001-2954 discloses a method of forming an ITO film through a liquid phase method using liquid material in which an indium organic acid compound and an organic tin compound are melted in an organic solvent. However, the ITO film obtained by the forming method has large sheet resistance and is not suitable for electrode application. Therefore, in JP-A-2004-22224, the dispersion liquid, in which ITO particles are dispersed in the liquid material, is used so as to obtain an ITO film having low sheet resistance.

However, when an ITO film is formed by a liquid phase method, liquid material is coated on a substrate, and the coated liquid material is then dried and hardened, thereby forming a thin film. In the method of forming an ITO film according to the related art, heating is generally performed in an oven in the drying/hardening process. However, the present inventor has proved that the sheet resistance of the ITO film obtained by the method increases over time. As the sheet resistance changes over time, electric characteristics of an electronic apparatus using the ITO film in an electrode or the like also change over time.

### SUMMARY

An advantage of some aspects of the invention is that it provides a method of forming a conductive film having low resistance and stable electric characteristics by using a liquid phase method.

According to an aspect of the invention, a method of forming a conductive film is provided which includes disposing liquid material containing particulate materials on a substrate; and baking the liquid material on the substrate through light-irradiation using a flash lamp so as to form a conductive film.

In the conductive film forming method, the light-irradiation treatment using a flash lamp is carried out when the liquid material is baked to obtain a conductive film composed of a particle sintered film. Accordingly, the liquid material is instantly heated to rapidly remove the dispersion medium in which the particulate materials are dispersed. Further, since the sintering of the particulate materials is performed by heat energy and light energy, it is possible to form a conductive film having a more stable conduction state, compared with a method according to the related art in which sintering is performed only by heat energy. This is because the crystallinity of the particle surface can be recovered by the assistance of light energy, and the necking or adhesion between the particles is stimulated by the light energy.

In the conductive film forming method, the particulate materials may be particles of a conductive material of which the bulk melting point is higher than 900° C., and of which the melting point in a particle diameter of 10 to 150 nm is higher than 255° C. In such a material which has a high melting point and in which the depression of melting point is small when it is microparticulated, when a conductive film is formed by using a liquid phase method in order to limit the heating temperature, the adhesion or sintering between particles is not sufficiently performed, and it is difficult to obtain a conductive film having an excellent electric characteristic. Therefore, the application of the forming method according to the invention stimulates the fusion bond between particles to obtain stable conduction, and is extremely effective even when a conductive film is formed by using the particulate materials having a high melting point.

Further, in the conductive film forming method, the particulate materials may be particles of a transparent conductive material. In general, particles of a transparent conductive material composed of metal oxide have a high melting point, and the depression of melting point is small when the particles are microparticulated. Therefore, it is difficult to perform the fusion bond or sintering through heating and to obtain a stable electric characteristic. Accordingly, the particulate materials are suitable for the forming method according to the invention.

Furthermore, in the conductive film forming method, the transparent conductive material may be at least one metal oxide which is selected from indium tin oxide, tin oxide, oxidized indium, indium zinc oxide, and halogen-containing tin oxide. The invention is particularly effective when a conductive film using the particles of those transparent conductive materials is formed.

In addition, in the conductive film forming method, the particulate material may be at least one metallic particulate material which is selected from copper, nickel, manganese, titanium, tantalum, tungsten, and molybdenum. In the metallic materials, the surface oxidation easily occurs in the air, and it is difficult to perform the fusion bond between the particles by heating and to obtain a stable electric characteristic. Therefore, the particulate material is suitable for the forming method according to the invention.

Furthermore, in the conductive film forming method, the liquid material may be disposed on the substrate by a droplet discharge method using a droplet discharge device, or may be disposed on the substrate by a CAP coating method using a capillary phenomenon.

According to another aspect of the invention, a method of manufacturing an electronic apparatus is provided which includes a conductive film forming process using the forming method according to the above aspects. In accordance with the manufacturing method, an electronic apparatus which is provided with a stable conductive film and is excellent in electrical reliability can be manufactured at low cost.

### BRIEF DESCRIPTION OF THE DRAWINGS

The invention will be described with reference to the accompanying drawings, wherein like numbers reference like elements.

FIG. 1 is a schematic view illustrating a droplet discharge device and droplet discharge head according to an embodiment.

FIGS. 2A to 2D are cross-sectional views for explaining a conductive film forming method according to an embodiment.

FIG. 3 is a graph for explaining an operational effect of the forming method according to the embodiment.

FIGS. 4A to 4D are cross-sectional views for explaining another embodiment of the conductive film forming method.

FIG. 5 is a plan view illustrating one arbitrary pixel of an active matrix substrate.

FIG. 6 is a circuit diagram of the active matrix substrate.

FIGS. 7A and 7B are process diagrams for explaining a method of manufacturing the active matrix substrate.

FIGS. 8A and 8B are process diagrams for explaining the method of manufacturing the active matrix substrate.

FIGS. 9A and 9B are process diagrams for explaining the method of manufacturing the active matrix substrate.

FIGS. 10A to 10C are process diagrams for explaining the method of manufacturing the active matrix substrate.

FIGS. 11A to 11C are process diagrams for explaining the method of manufacturing the active matrix substrate.

FIGS. 12A to 12C are process diagrams for explaining the method of manufacturing the active matrix substrate.

FIGS. 13A to 13C are process diagrams for explaining the method of manufacturing the active matrix substrate.

FIGS. 14A to 14C are process diagrams for explaining the method of manufacturing the active matrix substrate.

FIGS. 15A to 15C are process diagrams for explaining the method of manufacturing the active matrix substrate.

FIGS. 16A to 16C are process diagrams for explaining the method of manufacturing the active matrix substrate.

FIGS. 17A and 17B are diagrams illustrating an electro-optical device provided with the active matrix substrate.

FIG. 18 is a schematic view illustrating a conductive film forming device which is used for manufacturing another substrate for an electronic apparatus.

FIG. 19 is a perspective view illustrating the droplet discharge device which is applied to the conductive film forming device shown in FIG. 18.

FIG. 20 is a cross-sectional view illustrating a touch panel.

FIGS. 21A to 21C are perspective views showing examples of an electronic apparatus.

### DESCRIPTION OF EXEMPLARY EMBODIMENTS

Method of Forming Conductive Film

Hereinafter, preferred embodiments of the invention will be described with reference to the drawings.

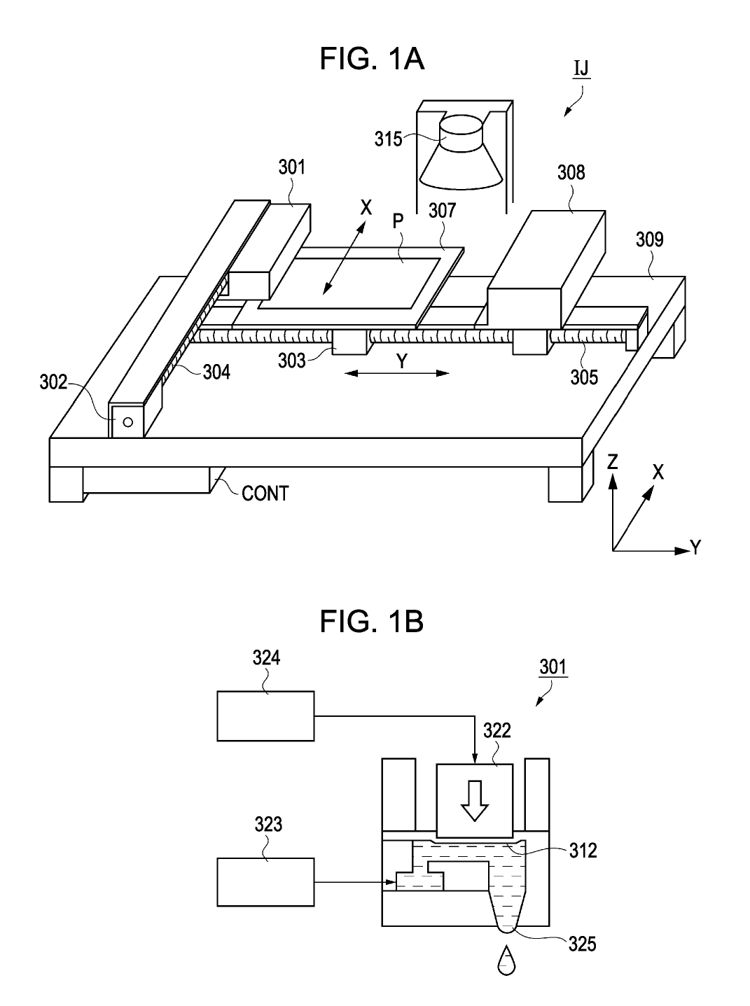

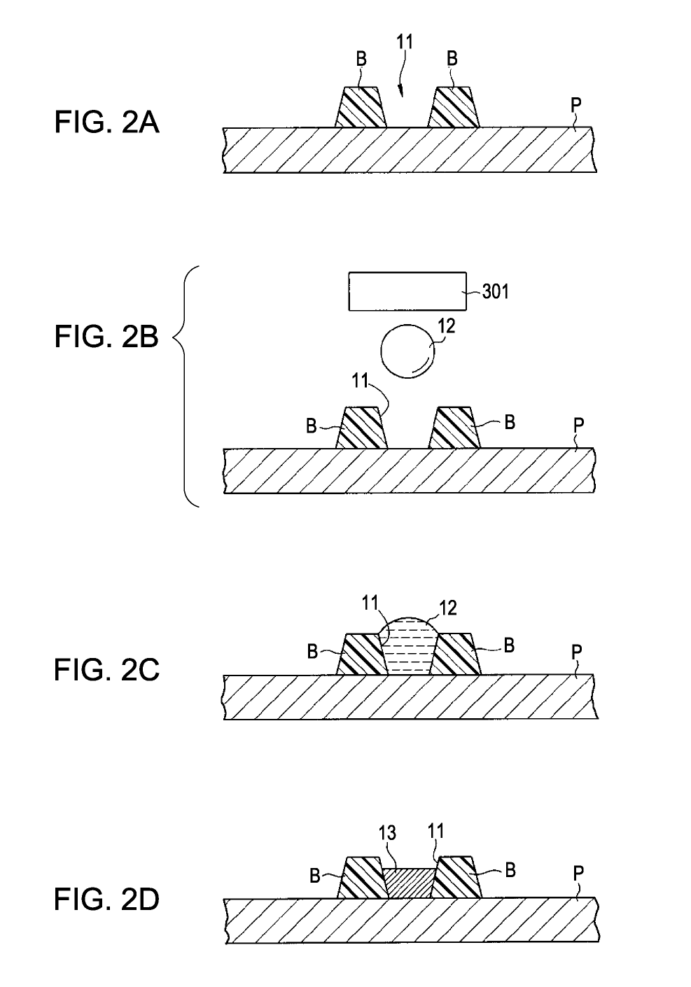

FIG. 1A is a schematic view illustrating a droplet discharge device which is used in a forming method according to the present embodiment, and FIG. 1B is a cross-sectional view for explaining the method of forming a conductive film. FIGS. 2A to 2D are cross-sectional views for explaining a conductive film forming method according to an embodiment.

Liquid Material

In the present embodiment, a case will be described, in which liquid material including particulate material is disposed on a substrate by using a droplet discharge method, and after, a conductive film pattern is formed. As the liquid material which is used in the forming method according to the present embodiment, material obtained by dispersing particulate material into a dispersion medium is used. A conductive film forming material which is suitable for forming a conductive film by using the forming method according to the present embodiment is a material which has a high bulk melting point and in which the depression of melting point is small when it is microparticulated. The conductive film forming material is preferable, when a conductive film is formed of particulate material in which the bulk melting point is higher than 900° C. and in which the melting point in a particle diameter of 10 to 150 nm is higher than 255° C. As the specific examples of the particulate material, there are provided base metals with a high melting point, such as copper, nickel, manganese, titanium, tantalum, tungsten, and molybdenum, and metal oxides such as an indium tin oxide, a tin oxide, an indium oxide, an indium zinc oxide, and a halogen-containing tin oxide. Particles of the metals and particles of the metal oxides may be subjected to coating which is aimed at enhancing dispersion and preventing degradation in the liquid material.

On the other hand, there is no limitation for a dispersion medium, as long as the dispersion medium can disperse the conductive particles and aggregation does not occur. In addition to water, there can be exemplified alcohols such as methanol, ethanol, propanol, and butanol, hydrocarbon-based compounds such as n-heptane, n-octane, decane, dodecane, tetradecane, toluene, xylene, cymene, durene, indene, dipentene, tetrahydronaphthalene, decahydronaphthalene, and cyclohexylbenzene, ether-based compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl)ether, and p-dioxane, and polar compounds such as propylene carbonate, γ-butyrolactone, N-methyl-2-pyrrolidone, dimethylformamide, dimethyl sulfoxide, and cyclohexanone. Among them, water, alcohols, hydrocarbon-based compounds, and ether-based compounds are preferable in terms of the dispersibility of particles, the stability of dispersion liquid, and the ease of application to the droplet discharge method. As a more preferable dispersion medium, water and hydrocarbon-based compounds can be exemplified.

The surface tension of the conductive particle dispersion liquid is preferably in the range of 0.02 N/m to 0.07 N/m. When liquid is discharged by a droplet discharge method, and if the surface tension is less than 0.02 N/m, the wettability of the liquid material composition with respect to a discharge nozzle surface increases, so that a flying curve of liquid easily occurs. If the surface tension exceeds 0.07 N/m, the shape of the meniscus at the leading end of the discharge nozzle becomes unstable, which makes it difficult to control a discharge amount or discharge timing. In order to adjust the surface tension, a small amount of surface tension regulating agent such as a fluorine-based agent, a silicon-based agent, or a nonionic agent may be added into the dispersion liquid within a range where the contact angle with a substrate is not significantly reduced. The nonionic surface tension regulating agent serves to improve the wettability of liquid with respect to a substrate, to improve the leveling properties of the film, and to prevent minute irregularities of film from being produced. The surface tension regulating agent may include, if necessary, organic compounds such as alcohol, ether, ester, and ketone.

Preferably, the viscosity of the dispersion liquid ranges from 1 mPa·s to 50 mPa·s. When the liquid material is discharged as droplets by using an inkjet method, and when the viscosity is smaller than 1 mPa·s, the peripheral portion of the discharge nozzle is easily contaminated by the outflow of liquid material. Further, when the viscosity is larger than 50 mPa·s, discharge nozzle holes are frequently clogged, so that smooth discharge of droplets becomes difficult and an amount of discharged droplets is reduced.

Droplet Discharge Device

Now, a droplet discharge device will be described with reference to the schematic block diagram of FIG. 1A. The droplet discharge device (inkjet device) IJ is provided with a droplet discharge head 301, an X-direction driving shaft 304, a Y-direction guide shaft 305, a control device CONT, a stage 307, a cleaning mechanism 308, a base 309, and a heater 315, and discharges (drops) droplets onto a substrate P from the droplet discharge head. The stage 307, which supports the substrate P on which liquid material is coated by the droplet discharge device IJ, is provided with a fixing mechanism (not shown) for fixing the substrate P at a reference position.

The droplet discharge head 301 is a multi-nozzle-type droplet discharge head provided with a plurality of discharge nozzles, and the longitudinal direction thereof coincides with the Y-axis direction. The plurality of nozzles are provided on the lower surface of the droplet discharge head 301 at a constant distance in parallel to the Y-axis direction. From the discharge nozzles of the droplet discharge head 301, liquid material including the above-described particulate material is discharged onto the substrate P which is supported by the stage 307.

The X-direction driving shaft 304 is connected to an X-direction driving motor 302. The X-direction driving motor 302 is a stepping motor or the like, which rotates the X-direction driving shaft 304 when an X-direction driving signal is supplied from the control device CONT. If the X-direction driving shaft 304 rotates, the droplet discharge head 301 moves in the X-axis direction.

The Y-direction driving shaft 305 is fixed so as not to move with respect to the base 309. The stage 307 is provided with a Y-direction driving motor 303. The Y-direction driving motor 303 is a stepping motor or the like, which moves the stage 307 in the Y-direction when a Y-direction driving signal is supplied from the control device CONT.

The control device CONT supplies a voltage for controlling droplet discharge to the droplet discharge head 301. Further, the control device CONT supplies a driving pulse signal, which controls the X-direction movement of the droplet discharge head 301, to the X-direction driving motor 302 and supplies a driving pulse signal, which controls the Y-direction movement of the stage 307, to the Y-direction driving motor 303.

The cleaning mechanism 308, which cleans the droplet discharge head 301, is provided with a Y-direction driving motor (not shown). The driving of the Y-direction driving motor causes the cleaning mechanism to move along the Y-direction guide shaft 305. The movement of the cleaning mechanism 308 is also controlled by the control device CONT.

The heater 315 is a flash lamp in the present embodiment. The heater 315 instantly heats the substrate P by light irradiation in which electric charges stored in a capacitor is discharged within a short time, so that the solvent included in the liquid material coated on the substrate P is evaporated and dried. The application and cut-off of power of the heater 315 is also controlled by the control device CONT. As a flash lamp, a xenon lamp can be exemplified, and such a lamp having the following properties can be preferably used: the light irradiation energy of 1 to 50 J/cm² and the light irradiation time of 1μ second to a few m seconds.

The droplet discharge device IJ discharges droplets onto the substrate P while relatively scanning the droplet discharge head 301 and the stage 307 supporting the substrate P. In the following description, the X direction is set to a scanning direction, and the Y direction orthogonal to the X direction is set to a non-scanning direction.

Therefore, the discharge nozzles of the droplet discharge head 301 are provided at a constant distance in parallel to the Y direction which is the non-scanning direction. In FIG. 1A, the droplet discharge head 301 is disposed orthogonally to the traveling direction of the substrate P. However, the angle of the liquid droplet discharge head 301 may be adjusted so that the liquid droplet discharge head 301 crosses the traveling direction of the substrate P. In accordance with that, adjusting the angle of the droplet discharge head 301 allows the pitches between the nozzles to be regulated. Further, the distance between the substrate P and the nozzle surface may be regulated.

FIG. 1B is a cross-sectional view illustrating the droplet discharge head 301. In the droplet discharge head 301, a piezoelectric element 322 is installed adjacent to a liquid chamber 321 containing liquid material (liquid material for wiring lines or the like). The liquid material is supplied to the liquid chamber 321 through a liquid material supply system 323 which includes a material tank containing the liquid material. The piezoelectric element 322 is connected to a driving circuit 324. Through the driving circuit 324, a voltage is applied to the piezoelectric element 322 so that the piezoelectric element 322 is deformed. Then, the liquid chamber 321 is deformed, so that the liquid material is discharged from the nozzle 325. In this case, a distortion amount of the piezoelectric element 322 is controlled by changing the value of the applied voltage. Further, a distortion speed of the piezoelectric element 322 is controlled by changing the frequency of the applied voltage. Since the droplet discharge through the piezoelectric system does not apply heat to the material, the composition of the material is not influenced.

Method of Forming Conductive Film

As a method of forming a conductive film according to an embodiment of the invention, a method in which a conductive film is patterned on a substrate by using a bank (dam) formed on the substrate will be described with reference to FIG. 2.

As the substrate P shown in FIG. 2A, a hard substrate made of glass, quartz, ceramic, or the like, or a flexible substrate made of plastic or the like can be used. The bank functions as a partition, and the formation of the bank can be performed by an arbitrary method such as a lithographic method or printing method. For example, a spin coat method, a spray coat method, a roll coat method, a die coat method, a dip coat method, and the like are used as the lithographic method, in which an organic photosensitive material is coated on the substrate P shown in FIG. 2A in accordance with the height of the bank, thereby forming a resist layer. Further, with a mask being set in accordance with the bank shape (forming region of conductive film), the resist layer is exposed and developed so as to be partially removed. Then, the banks B having a predetermined plan shape are formed on the substrate P. Further, the bank B may be formed of multiple layers composed of two or more layers, in which the lower layer is formed of an inorganic or organic material lyophilic with respect to functional fluid, and the upper layer is formed of an organic material having liquid-repellency. Accordingly, a formation region 11 surrounded by the banks B is formed as a region (having a width of 10 μm, for example) where a conductive film should be formed.

As an organic material forming the bank B, a material originally having liquid-repellency with respect to liquid material may be used. Further, as will be described below, an insulating organic material may be used, which can become liquid-repellent (fluorinated) through plasma treatment, has excellent adhesion with a base substrate, and is easily patterned by a lithographic method. For example, polymeric material such as acrylic resin, polyimide resin, olefin resin, melamine resin or the like can be used.

Next, in order to remove resist (organic material) residue in the formation region 11, the resist residue remaining when the banks are formed, residue treatment is performed with respect to the substrate P. As a residue treatment, it is possible to select an ultraviolet (UV) irradiation treatment that carries out the residue treatment by irradiation with ultraviolet light, an O₂ plasma treatment in which oxygen in the atmosphere serves as the treatment gas, and the like. Here, the O₂ plasma treatment is carried out.

Specifically, the O₂ plasma treatment is carried out by irradiating the substrate P with oxygen plasma from a plasma discharge electrode. The conditions for the O₂ plasma treatment are as follows: a plasma power ranges from 50 to 1000 W, an oxygen gas flow rate ranges from 50 to 100 ml/min, a conveyance speed of the substrate P with respect to the plasma discharge electrode ranges from 0.5 to 10 mm/sec, and a substrate temperature ranges from 70 to 90° C.

In the case where the substrate P is a glass substrate, the surface thereof has liquid-affinity with respect to the liquid material for forming a conductive film. However, it is possible to increase the liquid-affinity of the surface of the substrate P which is exposed on the bottom portion of the formation region 11 by performing the O₂ plasma treatment or ultra-violet irradiation treatment for the residue treatment as in the present embodiment.

Subsequently, the liquid-repelling treatment is carried out on the banks B so as to impart liquid-repellency on the surface thereof. As the repellency treatment, a plasma treatment method (CF₄ plasma treatment method) can be used, which is performed in the atmosphere with a processing gas set to tetrafluoromethane. The conditions for the CF₄ plasma treatment method are as follows: a plasma power ranges from 50 to 1000 W, a tetrafluoromethane gas flow rate ranges from 50 to 100 ml/min, a substrate conveyance speed with respect to the plasma discharge electrode ranges from 0.5 to 1020 mm/sec, and a substrate temperature ranges from 70 to 90° C. Moreover, the treatment gas is not limited to a CF₄ gas, but other fluorocarbon-based gases can be used.

By carrying out this type of liquid-repelling treatment, a fluorine group is introduced into the resin that forms the banks B, and high liquid-repellency is imparted to the substrate P. Note that the O₂ plasma treatment used as a liquid-affinity treatment can be carried out before formation of the banks B. However, because acrylic resins, polyimide resins and the like are easily fluoridated (liquid-repellent) when pretreatment using an O₂ plasma is carried out, the O₂ plasma treatment is preferably carried out after the bank B has been formed.

In the case when the substrate P is formed of glass, the liquid-repellency of the substrate P surface is not lost, due to the liquid-repelling treatment of the banks B. However, in accordance with a material of the substrate P, the substrate P surface that has undergone the liquid-affinity treatment can be influenced by the liquid repelling treatment. In this case, an oxidized silicon film as a base film that rarely repels liquid is formed on the substrate P surface, or the bank is formed of a material (fluorine resin) that is liquid-repellent, such that it is possible to omit the liquid-repellency treatment.

Next, as shown in FIG. 2B, the wiring pattern formation material is discharged on the substrate P which is exposed to the formation region 11 by using the above-described droplet discharge device IJ. For example, the liquid material 12 including ITO particles as particulate materials is discharged from the droplet discharge head 301. The droplet discharge can be performed in the following conditions: an ink weight is 4 ng/dot and a discharge speed is 5 to 7 m/sec. Preferably, in the atmosphere in which the droplets are discharged, the temperature is set to 60° C. or less and the humidity is set to 80% or less. In this state, the stabilized droplet discharge can be performed without the discharge nozzle of the liquid discharge head 301 being clogged.

At this time, since the substrate P which is exposed to the formation region 11 as a conductive film formation region is surrounded by the banks B, the liquid material 12 can be prevented from spreading outside a predetermined area. Further, although some of the discharged liquid material 12 is laid on the bank B, the liquid material is repelled from the bank B surface so as to flow in the formation region 11, because the surfaces of the banks B are liquid-repellent. Moreover, since the liquid-affinity is imparted to the substrate P surface exposed to the formation region 11, the discharged liquid material 12 uniformly spreads on the substrate P surface. As shown in FIG. 2C, the liquid material 12 can be uniformly disposed in the extending direction of the formation region 11.

After a predetermined amount of liquid material 12 is discharged and disposed on the substrate P, a drying/baking process is performed in order to remove the dispersion medium and make the conductive film solid. In this process, the drying process and the baking process may be performed separately. Alternately, the drying/baking may be performed through a batch heating process. In the case of the present embodiment, the drying/baking treatment is performed by a heating process through light irradiation using a flash lamp. The light irradiation conditions for the flash lamp are as follows: light irradiation energy of 1 to 50 J/cm² and light irradiation of 1 μs to a few milliseconds.

By the drying/baking treatment, the dispersion medium is removed, and the coating material on the particulate material is also removed, as shown in FIG. 2D. Then, the conductive film 13 in which the particulate material is aggregated so as to be in electric contact is formed on the substrate P. According to the forming method of the present embodiment, it is possible to obtain the conductive film 13 of which the sheet resistance hardly changes over time and which is provided with a stable electrical characteristic. In the forming method of the present embodiment, the substrate P is not heated by an oven or a hot plate but is instantly heated by using a flash lamp, in order to perform the drying/baking of the liquid material. Therefore, the crystallinity of the particle surface can be recovered by the assistance of light energy, and the necking or adhesion between the particles is stimulated by the light energy. As a result, a stable conductive state between the particles can be formed in the drying/baking process.

The drying/baking treatment may be performed in the atmosphere, but can be performed, if necessary, in an inert gas atmosphere such as nitrogen, argon, helium, or the like. The treatment temperature in the drying/baking process may be determined in consideration of the boiling point (vapor pressure) of the dispersion medium, the type and pressure of atmosphere gas, the thermal behavior such as the dispersibility or oxidative property of particles, the presence and amount of coating material, and the allowable temperature limit of the substrate. For example, in order to remove the coating material composed of an organic material, the baking treatment needs to be carried out at about 300° C. Further, when a substrate such as plastic is used, the drying/baking treatment is preferably carried out above the room temperature and below 100° C.

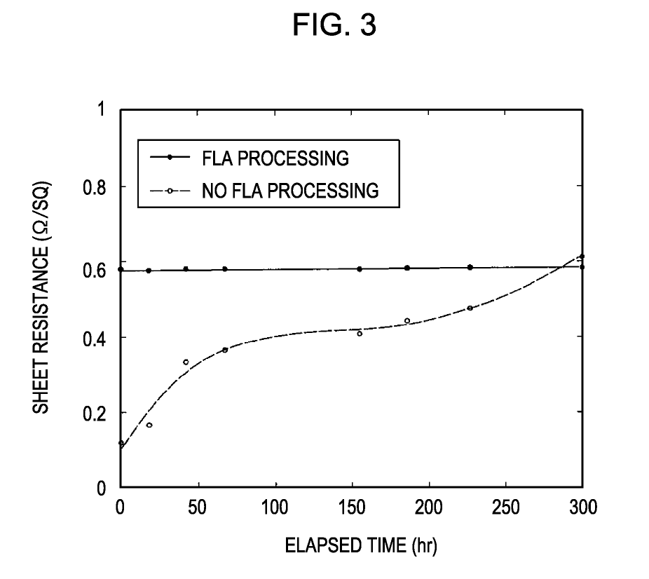

The effect of the forming method of the present embodiment will be described in detail with reference to FIG. 3. FIG. 3 is a graph showing results in which changes in sheet resistance over time are measured when an ITO film which is obtained by the forming method of the present embodiment and an ITO film in which the liquid material is dried and baked by using an oven are left in the atmosphere under the same condition.

In FIG. 3, a curved line corresponding to ‘FLA (flash lamp annealing) treatment’ indicates the measurement result of the ITO film formed by the forming method of the present embodiment, and a curved line corresponding to ‘no FLA treatment’ indicates the measurement result of the ITO film obtained by a conventional method using an oven. The treatment conditions of the drying/baking process are as follows.

Moreover, in the conditions of ‘no FLA treatment’, the atmosphere inside an oven is switched over in an order of ‘the air’, ‘an N₂ gas’, and ‘an N₂/H₂ gas’, in order to perform one-hour heating treatment in each atmosphere.

The drying/baking process of an ITO film that is subject to ‘FLA treatment’ is performed under the following conditions:

Treatment atmosphere: N₂,

Light irradiation energy: 6.4 J/cm²,

Irradiation time: 0.1 ms,

The number of irradiations: three, and

Cooling: rapidly cooling in the air after the flash lamp irradiation, and

Total treatment time: eight minutes.

The drying/baking process of an ITO film that is not subjected to ‘FLA treatment’ is performed under the following conditions:

Using a clean oven,

Hold temperature: 350° C., Treatment atmosphere: air->N₂->N₂/H₂,

Hold time: one hour in each atmosphere, and

Total treatment time: five hours (including a temperature rising/falling time).

As shown in FIG. 3, in the ITO film obtained in the forming method of the present embodiment, the sheet resistance hardly changes over time, while the initial sheet resistance is larger than that of the ITO film which is baked in an oven. Specifically, in the ITO film of ‘FLA treatment’, the sheet resistance immediately after the drying/baking treatment is 580 Ω/SQ, and the sheet resistance hardly changes (584 Ω/SQ) even after the ITO film is left for 300 hours. On the contrary, in the ITO film of ‘no FLA treatment’, the sheet resistance after the drying/baking treatment is 120 Ω/SQ, but the sheet resistance increases as time passes. After the ITO film is left for 186 hours, the sheet resistance becomes 444 Ω/SQ. Further, after it is left for 300 hours, the sheet resistance becomes 605 Ω/SQ, which is larger than that of the ITO film of ‘FLA treatment’.

According to the forming method of the conductive film of this embodiment as described above, the change in sheet resistance over time is minimized, so that the conductive film provided with a stable electric characteristic can be formed. Further, although the drying/baking process is carried out for a long time (five hours in the present example) in the related art, the time for the drying/baking treatment process can be reduced to a few minutes (eight minutes in the present example), which makes it possible to significantly improve the formation efficiency of the conductive film.

In the above-described embodiment, the droplet discharge method has been used as a coating method of liquid material. Without being limited thereto, various methods can be used as a coating method of liquid material. For example, a CAP coat method, a die coat method, a curtain coat method, and the like can be used in accordance with the coating form of liquid material.

Another Method of Forming Conductive Film

In the above embodiment, it has been described that the conductive film 13 is selectively formed on the substrate by using the banks B formed on the substrate P. However, as a pattern forming method of conductive film using a liquid phase method, a method can be used, in which the substrate P is surface-treated so that regions which have a different affinity with respect to the liquid material are formed to be separate on the substrate P, and the liquid material is selectively disposed by using the difference in affinity.

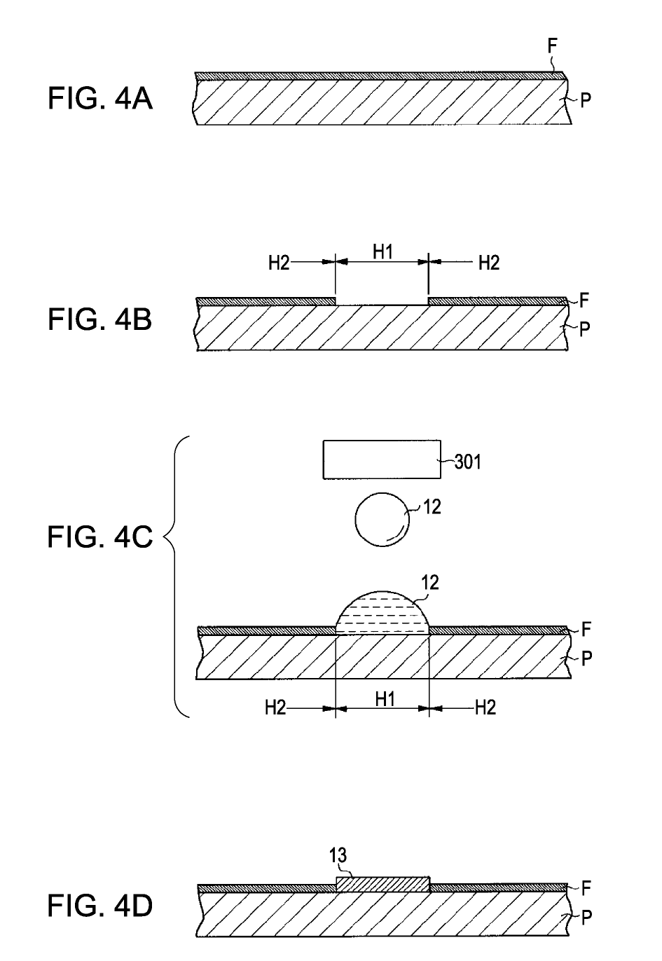

A case where a conductive film is formed by the above-described method will be described with reference to FIG. 4. FIGS. 4A to 4B are cross-sectional views showing a forming process of conductive film according to the present embodiment. The forming method of the present embodiment includes performing liquid-repellent treatment on the surface of the substrate P and selectively performing liquid-affinity treatment on a portion of the substrate P surface that has undergone the liquid-repellent treatment. As the liquid-repellent treatment, a method in which a self-organizing film is formed on the substrate P surface or a method in which the substrate P surface is directly subjected to the liquid-repellent treatment is used.

In the method of forming the self-organizing film, first, an organic molecular film F is formed on the substrate P surface where the conductive film will be formed, as shown in FIG. 4A. The organic molecular film F is composed of an organic molecule in which a functional group which is bondable to the substrate P surface and a functional group having a surface-modifying function which includes a liquid-affinity group and liquid-repellent group are connected by a carbon chain. Therefore, the organic molecular film F can be formed by uniformly adsorbing organic molecules on the substrate P surface.

Here, the self-organizing film includes a bonding functional group which can react with atoms constituting the base layer of a substrate, and other straight chain molecules. The self-organizing film is formed by orienting a compound which has an extremely high orientation characteristic due to the interaction of the straight chain molecules. Since this self-organizing film is made of oriented monomolecules, film thickness can be extremely thin, and the film is uniform at the molecular level. That is, since molecules with the same structures are positioned on the surface of the film, uniform and excellent liquid-affinity and liquid-repellency characteristics can be given to the surface of the film.

If a fluoroalkylsilane, for example, is used as the compound having a high orientation characteristics, the self-organizing film is formed by each compound being oriented such that the fluoroalkyl group positions on the surface of the film, so that uniform liquid-repellency can be imparted to the surface of the film.

As compounds for forming such a self-organizing film, there can be exemplified fluoroalkylsilanes (hereafter, referred to as “FAS”) such as heptadecafluoro-1,1,2,2-tetrahydrodecyltriethoxysilane, heptadecafluoro-1,1,2,2-tetrahydrodecyltrimethoxysilane, heptadecafluoro-1,1,2,2-tetrahydrodecyltrichlorosilane, tridecafluoro-1,1,2,2-tetahydrooctyltriethoxysilane, tridecafluoro-1,1,2,2-tetrahydrooctyltrimethoxysilane, tridecafluoro-1,1,2,2-tetrahydrooctyltrichlorosilane, and trifluoropropyltrimethoxysilane. For use, it is preferable to use one compound, but two or more types of compounds may be combined. In addition, it is possible to obtain adhesion with the substrate P and good liquid-repellency by using the FAS.

The FAS is generally expressed by a constitutional formula RnSiX₍₄₋ₙ₎. Here, n is an integer between 1 and 3 inclusive, X is a hydrolytic group such as a methoxy group, ethoxy group, or halogen atoms. In addition, R is a fluoroalkyl group, which has the structure of (CF₃)(CF₂)ₓ(CH₂)_{y} (where x is an integer between 0 and 10 inclusive, and y is an integer between 0 and 4 inclusive), and if a plurality of groups R or X are combined with Si, then all the groups R or X may be the same or different. The hydrolytic group expressed by X forms silanol by hydrolysis, and bonds with the substrate P by siloxane bonding through the reaction with the hydroxyl group in the base layer of the substrate P (glass, silicon). On the other hand, R has a fluoro group such as (CF₂) on the surface, which reforms the base layer surface of the substrate P into a surface which is difficult to wet (surface energy is low).

The self-organizing film is formed on the substrate P when the above-mentioned raw material compound and the substrate P are set in the same sealed container and left for 2 to 3 days at room temperature. In addition, when the entire sealed container is held at 100° C., the self-organizing film is formed on the substrate P in about three hours. This is a method of forming a self-organizing film from a vapor phase; however, a self-organizing film can be formed from a liquid phase as well. For example, when the substrate P is dipped into a solution containing the raw material compound, and is cleaned and dried, the self-organizing film is formed on the substrate P. It is desirable to perform pretreatment on the surface of the substrate P by irradiating ultraviolet light on the substrate P or cleaning it by using a solvent before forming the self-organizing film.

On the other hand, in the plasma processing method, plasma irradiation is performed on the substrate P at ordinary pressure or in a vacuum. Types of gases used for the plasma processing can be variously selected in consideration of the surface material of the substrate P, on which a wiring pattern should be formed, and the like. As process gases, for example, tetrafluoromethane, perfluorohexane, perfluorodecane, and the like can be exemplified. The treatment for making the surface of the substrate P liquid-repellent may be performed by adhering a film such as a polyimide film, which has been treated with tetrafluoroethylene so as to have desired liquid-repellency, to the surface of the substrate P. Further, a polyimide film, which has high liquid-repellency, may be used as the substrate P.

Thus, by performing the self-organizing film fabricating method, the organic molecular film F is formed on the surface of the substrate P. Next, as shown in FIG. 4B, the liquid-repellency of a region (conductive film formation region) where the liquid material should be coated is reduced, such that liquid-affinity is imparted only to a specific region of the substrate P surface. A method of irradiating ultraviolet light at a wavelength of 170 to 400 nm can be used for the liquid-affinity treatment. At this time, by irradiating ultraviolet light by using a mask in accordance with the plan shape of a conductive film, it is possible to selectively reform only a conductive film forming region on the substrate P which has undergone the liquid-repelling treatment and to make the part lyophilic. That is, by performing the above-mentioned liquid-repelling treatment and liquid-affinity treatment, a liquid-affinity region H1 corresponding to a region in which a conductive film should be patterned and a liquid-repelling region H2 surrounding the liquid-affinity section H1 are formed on the substrate P. Moreover, although it is possible to adjust the extent of reduction of liquid-repellency by the irradiation period of ultraviolet light, it is also possible to adjust the extent by the combination of intensity and wavelength of ultraviolet light, and heat treatment (heating), and the like.

As other methods of the liquid-affinity treatment, the plasma processing in which oxygen is used as a reactive gas may be used. Specifically, it is performed by irradiating oxygen plasma from a plasma discharge electrode to the substrate P. As conditions for O₂ plasma processing, for example, plasma power is 50 to 1000 W, an oxygen gas flow rate is 50 to 100 ml/min, the conveyance speed of the substrate P with respect to the plasma discharge electrode is 0.5 to 10 mm/sec, and substrate temperature is 70 to 90° C.

Further, a contact angle of the liquid-affinity section H1 with respect to the liquid material containing particulate materials is preferably set at 10° or less by adjusting the plasma processing conditions, for example, by lengthening the plasma processing time by making the transportation speed of the substrate P slow. Furthermore, as another liquid-affinity treatment, it is also possible to use the treatment of exposing a substrate to an ozone atmosphere.

If the liquid-affinity region H1 and the liquid-repelling region H2 are formed, the liquid material is discharged and disposed on the liquid-affinity region (conductive film formation region) H1 by using the droplet discharge head 301 (droplet discharge device IJ), as shown in FIG. 4C. At this time, the liquid-repellency is imparted to the liquid-repelling region H2 surrounding the liquid-affinity region H1 so that the liquid material is repelled. Therefore, even though some of the discharged liquid material is laid on the liquid-repelling region H2, the liquid material is repelled so as to be confined in the liquid-affinity region H1. Further, since the liquid-affinity to the liquid material is imparted to the liquid-affinity region H1, the discharged liquid material uniformly spreads within the liquid-affinity region H1. Accordingly, the liquid material is accurately and uniformly disposed at a predetermined position of the substrate P.

After that, the substrate P is subjected to the drying/baking process using a flash lamp, similar to the forming method using the banks. Then, as shown in FIG. 4D, the conductive film 13 having a predetermined plan shape can be formed on the substrate P. The light irradiation conditions of the flash lamp in the drying/baking process may be the same as the previous embodiment.

In the above embodiment, it has been described that the droplet discharge method is used as a coating method of the liquid material. Without being limited to the droplet discharge method, various coating methods can be used as a coating method of the liquid material. For example, a CAP coat method, a die coat method, a curtain coat method and the like can be used in accordance with the coating form of the liquid material.

Method of Manufacturing Electro-Optical Device

Now, as an example of a method of manufacturing an electronic apparatus including the conductive film forming process of the forming method of conductive film according to the invention, a method of manufacturing an electro-optical device, or specifically, a method of manufacturing an active matrix substrate constituting the electro-optical device will be described.

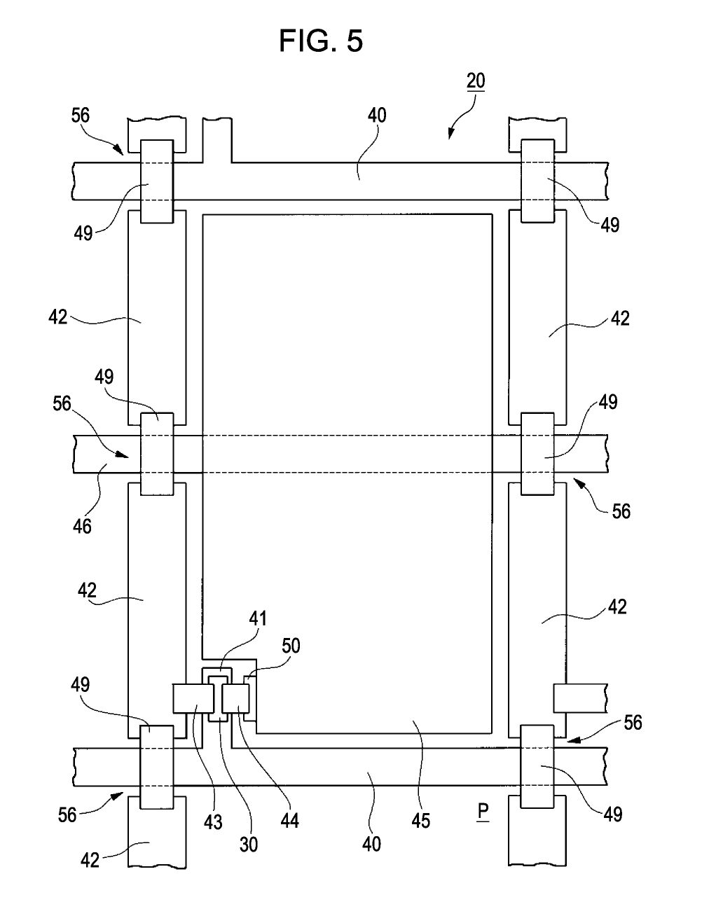

FIG. 5 is an enlarged diagram showing a portion of an active matrix substrate which is suitable for using the conductive film forming method according to the invention. The active matrix substrate 20 is provided with gate wiring lines 40 and source wiring lines 42 which are wired in a lattice shape. The plurality of gate wiring lines 40 are formed so as to extend in the X direction (first direction), and the plurality of source wiring lines 42 are formed so as to extend in the Y direction (second direction). The gate wiring line 40 is connected to a gate electrode 41, on which a TFT 30 is disposed with an insulating layer interposed therebetween. On the other hand, the source wiring line 42 is connected to a source electrode 42 of which one end is electrically connected to the TFT (switching element) 30.

In a region surrounded by the gate wiring lines 40 and the source wiring lines 42, a pixel electrode 45 is disposed so as to be electrically connected to the TFT 30 through a drain electrode 44. On the active matrix substrate 20, a capacitance line 46 is provided so as to extend substantially parallel to the gate wiring line 40. The capacitance line 46 is disposed in the lower layer of the pixel electrode 45 and the source wiring lines 42 through an insulating layer. The gate wiring lines 40, the gate electrode 41, the source wiring lines 42, and the capacitance line 46 are formed on the same wiring layer on the substrate.

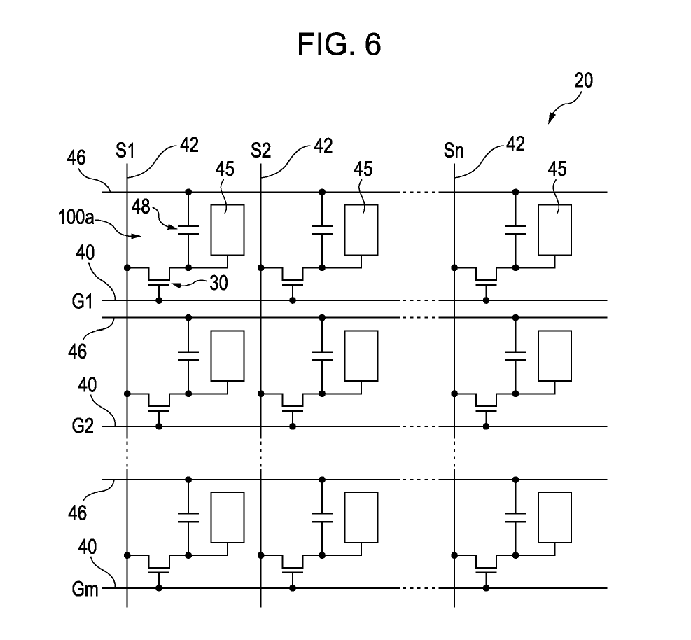

FIG. 6 is an equivalent circuit diagram of the active matrix substrate 20. The active matrix substrate 20 has a plurality of pixels 100a arranged in a matrix shape in a plan view. In the respective pixels 100a, the TFT 30 for switching pixels is formed. The source wiring line 42 which supplies pixel signals S1, S2, . . . , Sn is electrically connected to the source of the TFT 30. The pixel signals S1, S2, . . . , Sn written in the source wiring line 42 may be sequentially supplied in the above-mentioned order, or may be supplied group-by-group which is constituted by the plurality of source wiring lines 42 adjacent. The gate wiring lines 40 are electrically connected to the gates of the TFT 30, and are constituted so that scanning signals G1, G2, . . . , Gm may be applied to the gate wiring lines 40 line-by-line in the above-mentioned order at a predetermined timing in a pulse mode.

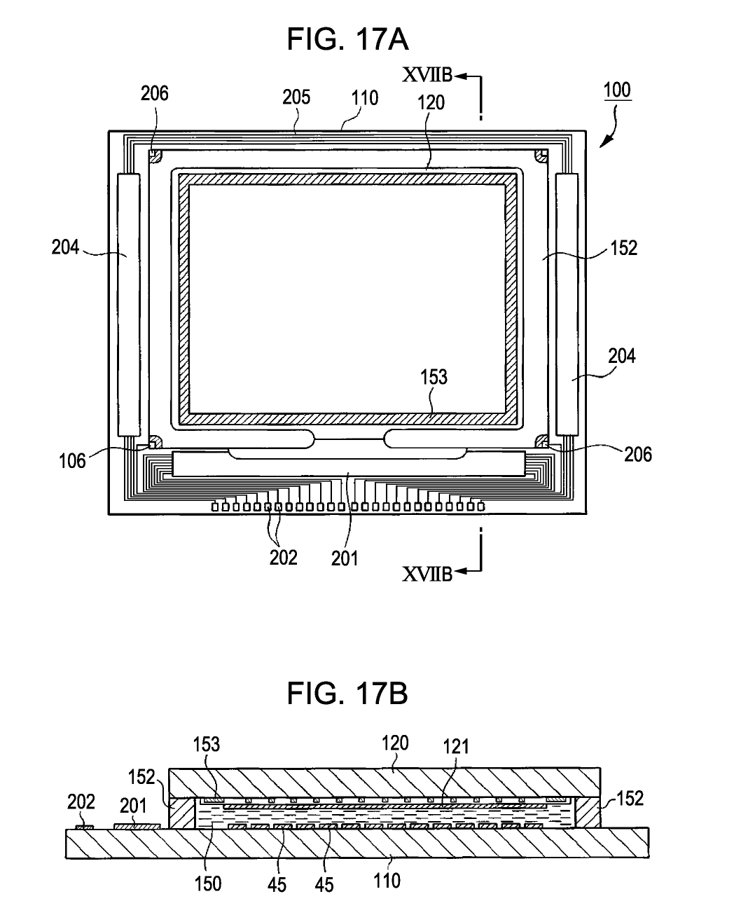

Each pixel electrode 45 is electrically connected to the drain of the TFT 30. Further, when the TFT 30 serving as a switching element is turned on only for a constant period, the pixel signals S1, S2, . . . , Sn supplied from the source wiring lines 42 are written into each pixel at a predetermined timing. As such, the pixel signals S1, S2, . . . , Sn with a predetermined level, which have been written into liquid crystal through the pixel electrode 45, are held between a counter electrode 121 of a counter substrate 120 shown in FIG. 17 and the pixel electrode for a constant period.

In order to prevent the held pixel signals S1, S2, . . . , Sn from leaking, storage capacitors 48 are added in parallel to liquid crystal capacitors, which are formed between the pixel electrode 45 and counter electrode 121 by the capacitance line 46. For example, the voltage of the pixel electrode 45 can be retained by the storage capacitor 48 for a period that is three orders of magnitude longer than the period for which the source voltage is applied. Thereby, the holding property of electric charges is improved and it is possible to implement the liquid crystal display device 100 with a high contrast ratio.

Method of Manufacturing Active Matrix Substrate

Now, a method of manufacturing the active matrix substrate 20 will be described.

The method of manufacturing the active matrix substrate according to the present embodiment includes a first process of forming wiring lines with a lattice pattern on the substrate P, a second process of forming a laminate section 35, and a third process of forming the pixel electrode 45.

First Process: Forming Wiring Lines

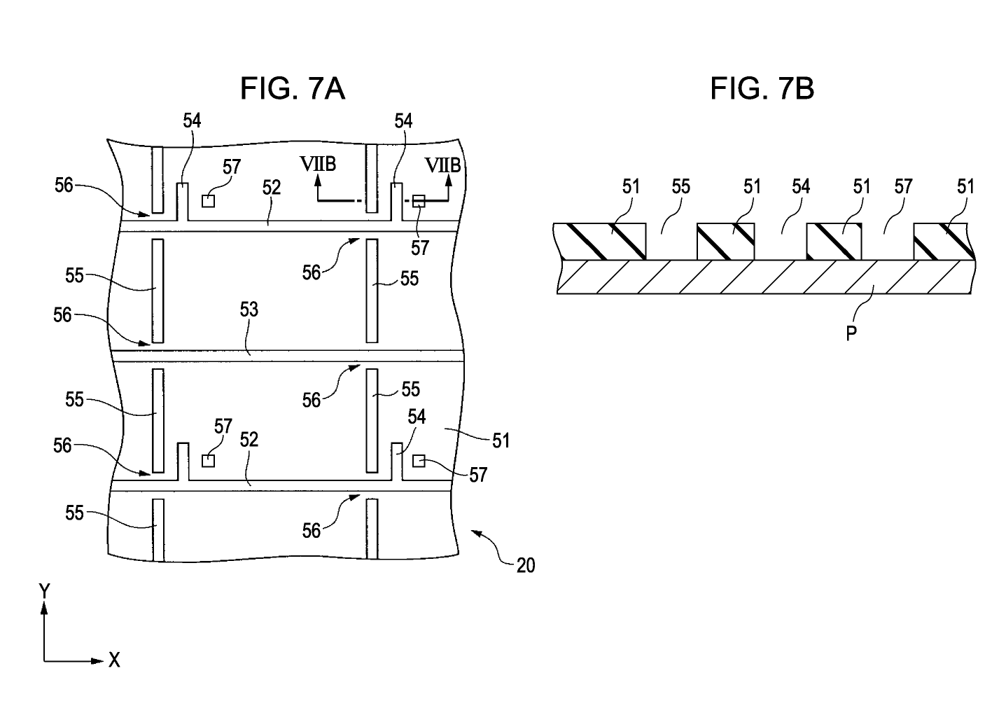

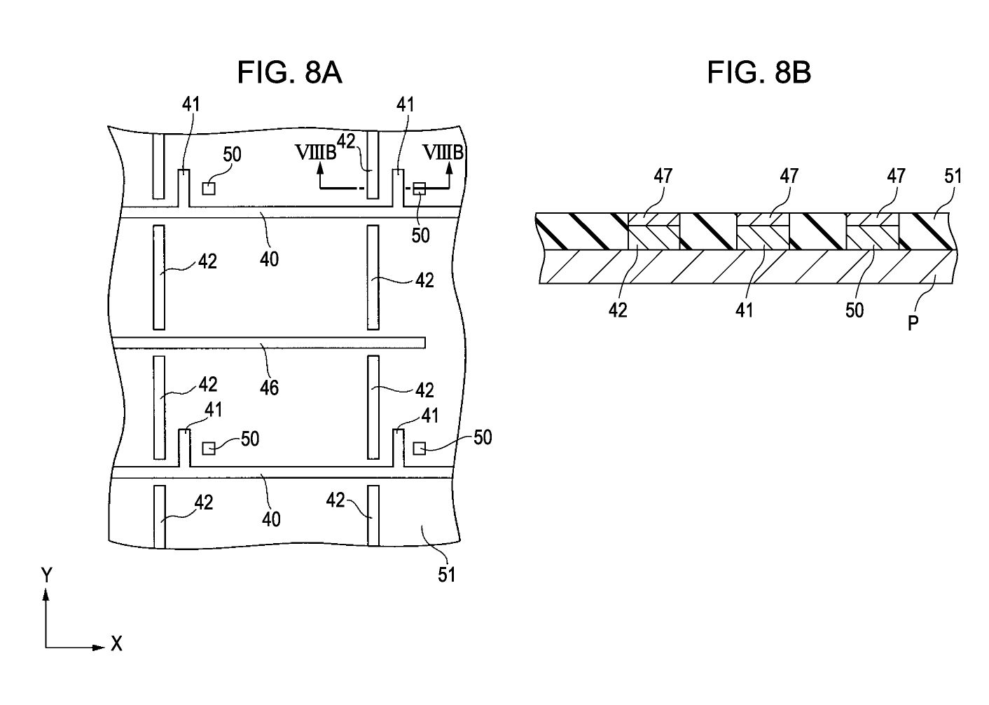

FIGS. 7 and 8 are diagrams explaining a wiring line forming process as the first process. Further, FIGS. 7B and 8B are cross-sectional views taken along the lines VIIB-VIIB and VIIIB-VIIIB of FIGS. 7A and 8A, respectively.

As the substrate P on which the wiring lines with a lattice pattern such as the gate wiring lines 40 or source wiring lines 42 are formed, various materials such as glass, quartz glass, a Si wafer, a plastic film, a metallic plate or the like can be used. On the surface of the various material substrates, a semiconductor film, a metallic film, a dielectric film, an organic film, or the like may be formed as a base layer.

First, as shown in FIG. 7, a bank 51 made of an insulating material are formed on the substrate P. The bank serves to dispose liquid material for the wiring lines, which will be described below, at a predetermined position of the substrate P. Specifically, as shown in FIG. 7A, the bank 51 having a plurality of opening sections 52, 53, 54, and 55 corresponding to the formation position of the wiring lines with a lattice pattern is formed on the upper surface of the cleaned substrate P by using a photolithographic method.

As a material of the bank 51, for example, a polymeric material such as acrylic resin, polyimide resin, olefin resin, melamine resin or the like is used. Further, in consideration of heat resistance or the like, a material including inorganic substances can be used. As an inorganic bank material, there are exemplified a high-molecular inorganic material or photosensitive inorganic material including silicon in the main chain, such as polysilazane, polysiloxane, siloxane-based resist, polysilane-based resist or the like, a spin on glass film, a diamond film, and a fluorinated amorphous carbon film including any one of silica glass, alkylsiloxane polymer, alkylsilsesquioxane polymer, hydrogenated alkylsilsesquioxane polymer, polyacryl ether, and the like. Further, as an inorganic bank material, an aerogel, porous silica, and the like are exemplified. When a photosensitive material such as a photosensitive polysilazane composition including polysilazane or a photo-acid generating agent is used, a resist mask is not needed, which is preferable.

The bank 51 is subjected to the liquid-repellency treatment, in order to reliably dispose the liquid material for wiring lines into the opening sections 52, 53, 54, and 55. As the liquid-repellency treatment, CF₄ plasma treatment (plasma treatment using a gas having a fluorine component) or the like is performed. Instead of the CF₄ plasma treatment, a liquid-repellent component (such as a fluorine group) may be filled in the material of the bank 51 in advance.

The opening sections 52, 53, 54, and 55 formed by the bank 51 correspond to the wiring lines with a lattice pattern such as the gate wiring lines 40 or the source wiring lines 42. In other words, the wiring lines with a lattice pattern such as the gate wiring lines 40 or the source wiring lines 42 are formed by disposing the liquid material for wiring lines into the opening sections 52, 53, 54, and 55 of the bank 51.

Specifically, the opening sections 52 and 53 formed to extend in the X direction respectively correspond to the formation position of the gate wiring line 40 and the capacitance line 46. Further, the opening section 52 corresponding to the formation position of the gate wiring line 40 is connected to the opening section 54 corresponding to the formation position of the gate electrode 41. In addition, the opening section 55 formed to extend in the Y direction corresponds to the formation position of the source wiring line 42. Moreover, the opening sections 55 extending in the Y direction are formed to be separate in an intersection section 56 so as not to intersect the opening sections 52 and 53 extending in the X direction.

Next, the liquid material for wiring lines including particulate materials is discharged into the opening sections 52, 53, 54, and 55 by the above-described droplet discharge device IJ, thereby forming the wiring lines with a lattice pattern composed of the gate wiring lines 40 and the source wiring lines 42 on the substrate. As described above, the liquid material for wiring lines is composed of dispersion liquid in which particulate materials such as metal or metal oxide are dispersed in a dispersion medium. As particulate materials, a conductive metal oxide such as ITO can be used, in addition to metallic particles such as nickel, manganese, titanium or the like.

After the liquid material for wiring lines is discharged onto the substrate P, the drying/baking treatment using the same flash lamp as that of the conductive film forming method of the previous embodiment is performed, in order to remove the dispersion medium so as to obtain a solid conductive film. By the drying/baking treatment, the electric contact between the particles is secured, and the conversion from the liquid material into the conductive film is performed.

On the wiring lines such as the gate wiring lines 40 and the source wiring lines 42, a metallic protecting film 47 may be formed, as shown in FIG. 8. The metallic protecting film 47 is a thin film which suppresses the (electro) migration of the formed conductive film. For example, the metallic protecting film 47 can be formed of nickel. The metallic protecting film 47 can be formed on the substrate P by the conductive film forming method according to the droplet discharge method. Alternately, only the metallic protecting film 47 may be formed by using an electroless plating method.

Through the above-described process, a layer composed of the bank 51 and the wiring lines with a lattice pattern is formed on the substrate P, as shown in FIG. 8.

Second Process: Forming Laminate Section

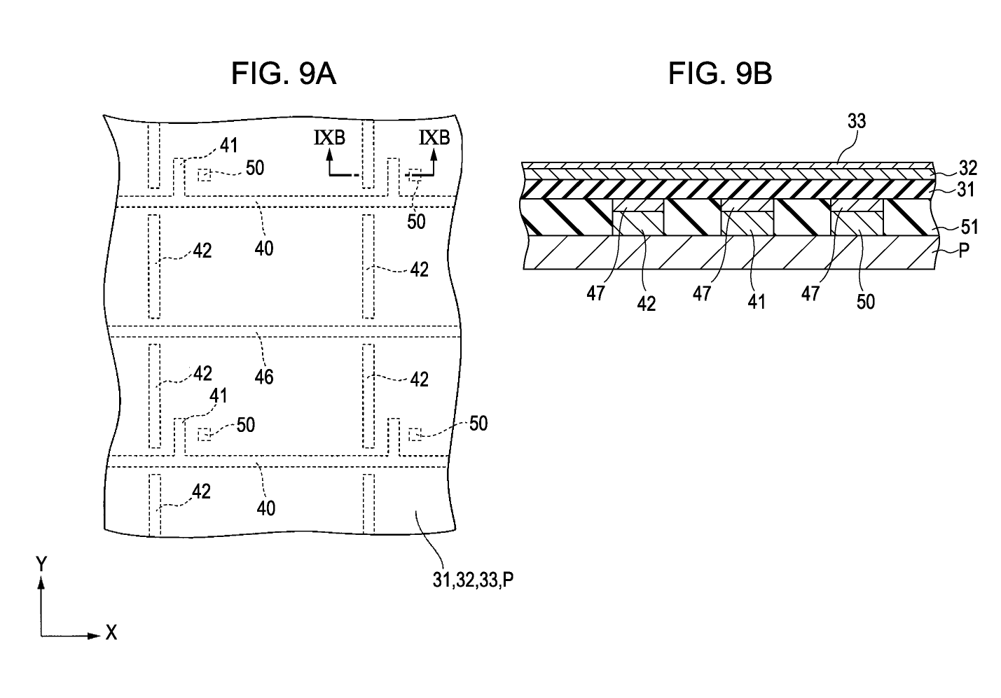

FIGS. 9 to 12 are diagrams for explaining the laminate section forming process as the second process. FIGS. 9B to 12B are cross-sectional views taken along the lines IXB-IXB, XB-XB, XIB-XIB, and XIIB-XIIB in the FIGS. 9A to 12A, respectively. FIGS. 9C to 12C are cross-sectional views taken along the lines IXC-IXC, XC-XC, XIC-XIC, and XIIC-XIIC in the FIGS. 9A to 12A.

In the second process, a laminate section 35 composed of an insulating film 31 and a semiconductor film (a contact layer 33 and an active layer 32) is formed at a predetermined position on the layer composed of the bank 51 and the wiring lines with a lattice pattern.

In the present process, a wiring layer is newly formed on the wiring layer (the gate wiring lines 40 and the like) formed in the first process. However, the surface of the bank 51 for forming wiring lines has undergone the liquid-repellency treatment in the first process. Therefore, if a source electrode or the like is directly formed on the surface of the corresponding bank 51, liquid material for forming an electrode is repelled by the bank 51, such that an excellent film pattern cannot be formed. Accordingly, in the present process, the surface of the bank 51 serving as a base is previously subjected to the liquid-affinity treatment before forming a source electrode and the like. As the liquid-affinity treatment, ultraviolet irradiation treatment or O₂ plasma treatment in which oxygen in the atmosphere serves as the treatment gas can be selected. Further, the combination thereof may be used. The O₂ plasma treatment is carried out by irradiating the substrate P with oxygen plasma from a plasma discharge electrode. The conditions for the O₂ plasma treatment are as follows: plasma power ranges from 50 to 1000 W, an oxygen gas flow rate ranges from 50 to 100 ml/min, a conveyance speed of the substrate P with respect to the plasma discharge electrode ranges from 0.5 to 10 mm/sec, and a substrate temperature ranges from 70 to 90° C.

After the surface of the bank 51 is subjected to the liquid-affinity treatment, the insulating layer 31, the active layer 32, and the contact layer 33 are consecutively formed on the overall surface of the substrate P by a plasma CVD method. Specifically, as shown in FIG. 9, a silicon nitride film as the insulating film 31, an amorphous silicon film as the active layer 32, and an n⁺-type silicon film as the contact layer 33 are consecutively formed by changing raw material gases and plasma conditions.

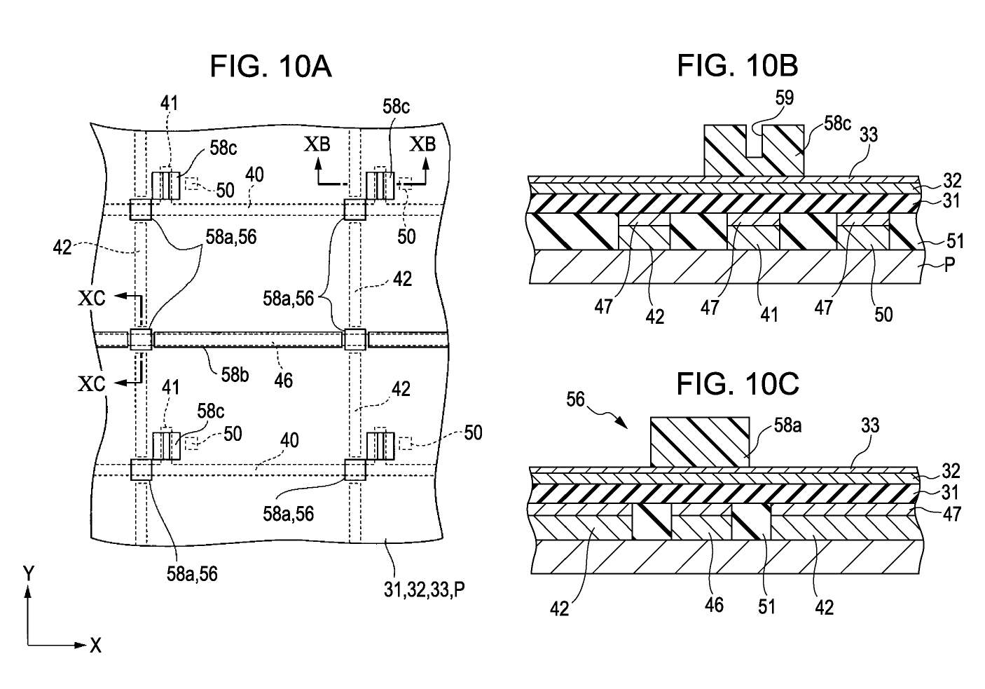

Next, as shown in FIG. 10, resist 58 (58a to 58c) is disposed at a predetermined position by using a photolithographic method. The predetermined position is set to the upper side of the intersection sections 56 between the gate wiring lines 40 and the source wiring lines 42, the upper side of the gate electrode 41, and the upper side of the capacitance line 46, as shown in FIG. 10A.

The resist 58a disposed on the intersection section 56 and the resist 58b disposed on the capacitance line 46 are formed so as not to come in contact with each other. Further, as shown in FIG. 10B, the resist 58c disposed on the gate electrode 41 is subjected to half-exposure, thereby forming a groove 59.

Next, etching treatment is carried out on the overall surface of the substrate P so as to remove the contact layer 33 and the active layer 32. Further, the etching treatment is carried out to remove the insulating film 31.

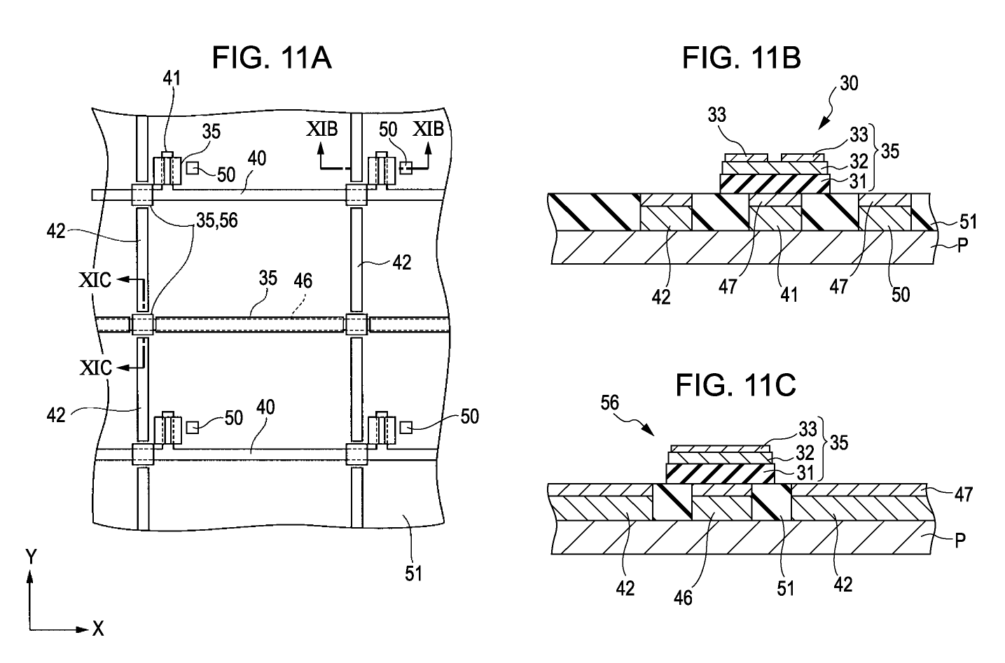

Accordingly, the contact layer 33, the active layer 32, and the insulating film 31 are removed from the region excluding a predetermined position where the resist 58 (58a to 58c) is disposed. Further, as shown in FIG. 11, the laminate section 35 composed of the insulating film 31 and the semiconductor film (the contact layer 33 and the active layer 32) is formed at the predetermined position where the resist 58 is disposed.

In the laminate section 35 formed on the gate electrode 41, the resist 58 is subjected to the half-exposure to form the groove 59. Therefore, the groove penetrates by developing the resist once again before etching. As shown in FIG. 11B, a portion of the contact layer 33 corresponding to the groove 59 is removed so that the contact layer 33 is divided into two layers. Accordingly, the TFT 30 as a switching element composed of the active layer 32 and the contact layer 33 is formed on the gate electrode 41.

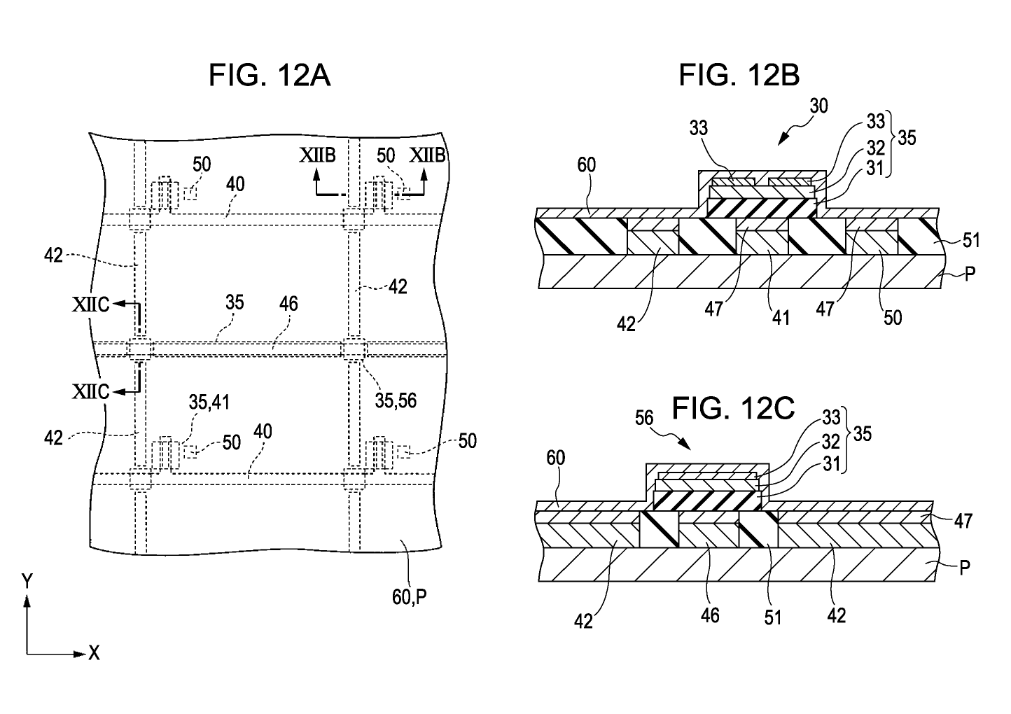

After that, a nitride silicon film as a protecting film 60 which protects the contact layer 33 is formed on the overall surface of the substrate P, as shown in FIG. 12. As such, the formation of the laminate section 35 is completed.

Third Process

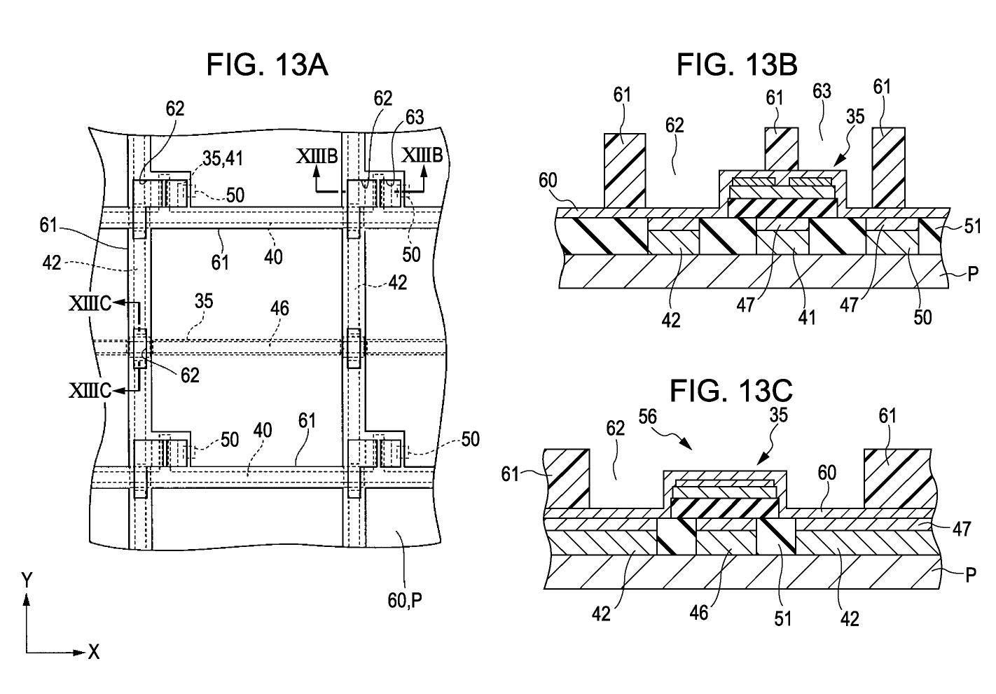

FIGS. 13 to 16 are diagrams for explaining the forming process of the pixel electrode 45 or the like, which is the third process. FIGS. 13B to 16B are cross-sectional views taken along the lines XIIIB-XIIIB, XIVB-XIVB, XVB-XVB, and XVIB-XVIB in the FIGS. 13A to 16A, respectively. FIGS. 13C to 16C are cross-sectional views taken along the lines XIIIC-XIIIC, XIVC-XIVC, XVC-XVC, and XVIC-XVIC in the FIGS. 13A to 16A, respectively.

In the third process, a source electrode 43, a drain electrode 44, a conductive layer 49, and a pixel electrode 45 are formed. The source electrode 43, the drain electrode 44, and the conductive layer 49 can be formed of the same material as the gate wiring lines 40 and the source wiring lines 42. Preferably, the pixel electrode 45 is formed of an optically-transparent material such as ITO, because it is required to be transparent. In forming these components, the conductive film formation method of the invention using the droplet discharge method is applied, similar to the first process.

First, a bank 61 is formed on the basis of a photolithographic method so as to cover the gate wiring lines 40 and the source wiring lines 42. In other words, as shown in FIG. 13, the bank 61 with a substantial lattice shape is formed. Moreover, an opening section 62 is formed in the intersection section 56 between the source wiring line 42 and the gate wiring line 40 and in the intersection section 56 between the source wiring line 42 and the capacitance line 46. In the position corresponding to the drain region of the TFT 30, an opening section 63 is formed.

As shown in FIG. 13B, the opening sections 62 and 63 are formed so as to expose a portion of the laminate section 35 (TFT 30) formed on the gate electrode 41. In other words, the bank 61 is formed so as to divide the laminate section 35 (TFT 30) into two parts in the X direction.

As the material of the bank 61, a polymeric material such as acrylic resin, polyimide resin, olefin resin, melamine resin or the like is used, similar to the bank 51. It is preferable that the surface of the bank 61 has liquid-repellency. However, if the liquid-repellency treatment such as CF₄ plasma treatment is performed, the bank 51 which has undergone the liquid-affinity treatment is once again subjected to the liquid-repellency treatment. Therefore, the bank 61 is preferably formed of a material in which a liquid repellent component (a fluorine group or the like) is filled in advance.

The opening section 62 formed by the bank 61 corresponds to the formation position of the conductive layer 49 connecting the divided source wiring lines 42 or the source electrode 43, and the opening section 63 formed in the bank 61 corresponds to the formation position of the drain electrode 44. Further, the region surrounded by the bank 61 in the other portions corresponds to the formation position of the pixel electrode 45. If the liquid material is disposed in the opening sections 62 and 63 of the bank 61 and in the region surrounded by the bank 61, the conductive layer 49 connecting the divided source wiring lines 42, the source electrode 43, the drain electrode 44, and the pixel electrode 45 can be formed.

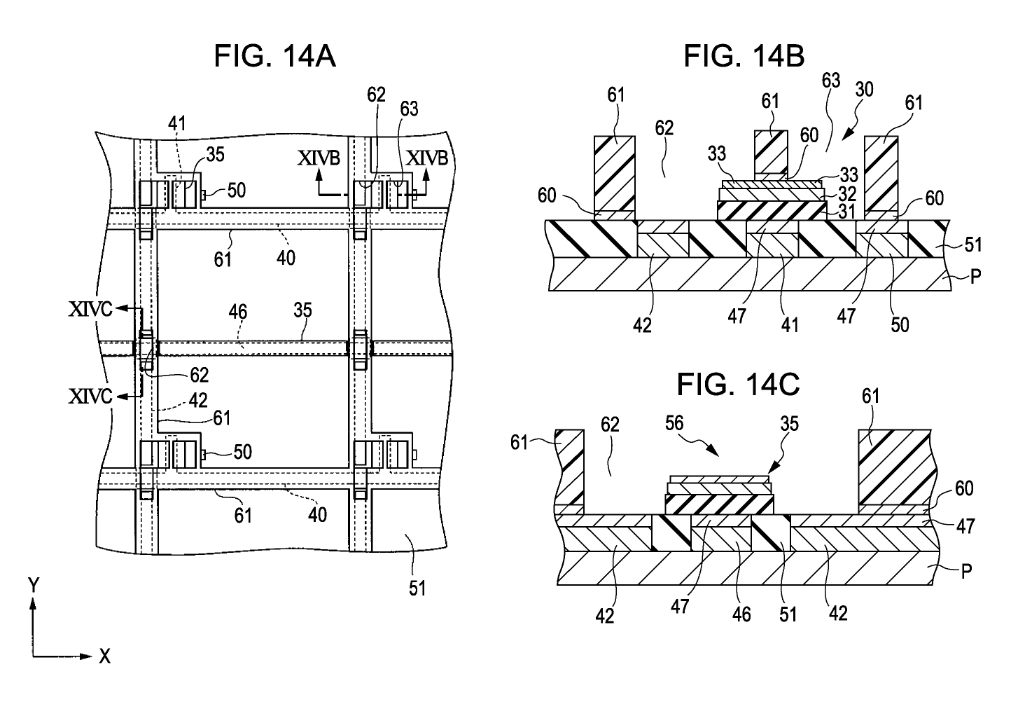

Next, the protecting film 60 formed on the overall surface of the substrate P is removed by etching treatment. Accordingly, as shown in FIG. 14, the protecting film 60 formed on the region where the bank 61 is not disposed is removed. Moreover, the metallic protecting layer 47 formed on the wiring lines with a lattice pattern is also removed.

Next, liquid material for an electrode including an electrode material of the source electrode 43 and the drain electrode 44 is discharged and disposed into the opening sections 62 and 63 of the bank 61 by the above-described liquid discharge device IJ. As the liquid material for an electrode, the same material as the liquid material for wiring lines, which are used for forming the gate wiring lines 40 and the like, can be used. After the liquid material for an electrode is discharged onto the substrate P, drying/baking treatment, if necessary, is carried out to remove the dispersion medium. By the drying/baking treatment, the electric contact between the conductive particles is secured, and the liquid material for an electrode is converted into a conductive film.

In the drawing, the source electrode 43 or the drain electrode 44 is formed of a single layer film. However, the electrodes may be formed of a laminate film composed of a plurality of layers. For example, the electrodes can be formed of a conductive member with a three-layer structure in which a barrier metal layer, a base layer, and a covering layer are laminated. The barrier metal layer and the covering layer can be formed of at least one metallic material selected from nickel, titanium, tungsten, manganese and the like. The base layer can be formed of at least one metallic material selected from silver, copper, aluminum, and the like. These layers can be sequentially formed by repeating the material disposing process and the intermediate drying process.

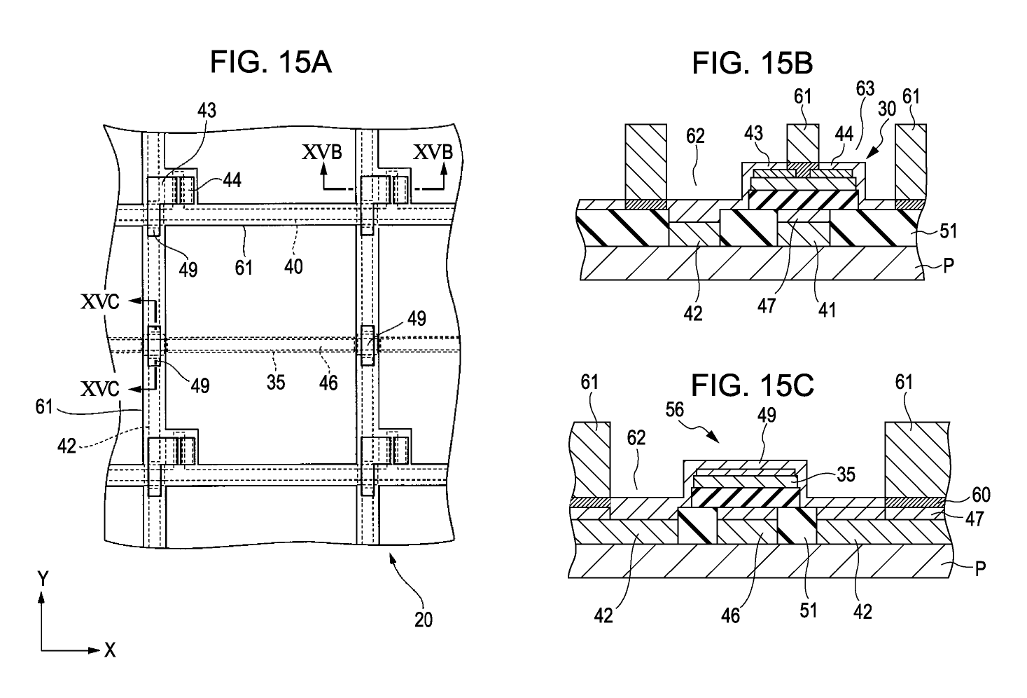

As such, the conducive layer 49 connecting the divided source wiring lines 42, the source electrode 43, and the drain electrode 44 are formed on the substrate P, as shown in FIG. 15.

Next, a portion of the bank 61 which is positioned in the boundary between the pixel electrode 45 and the drain electrode 44 is removed by laser or the like, and liquid material for pixel electrode including the material of the pixel electrode 45 is discharged and disposed into the region surrounded by the bank 61. The liquid material for pixel electrode is dispersion liquid in which conductive particles such as ITO are dispersed into a dispersion medium. After the liquid material for pixel electrode is discharged onto the substrate P, the drying/baking treatment using a flash lamp is performed in order to remove the dispersion medium. By the drying/baking treatment, the electric contact between the conductive particles is secured, and the liquid material for the electrode is converted into a conductive film.

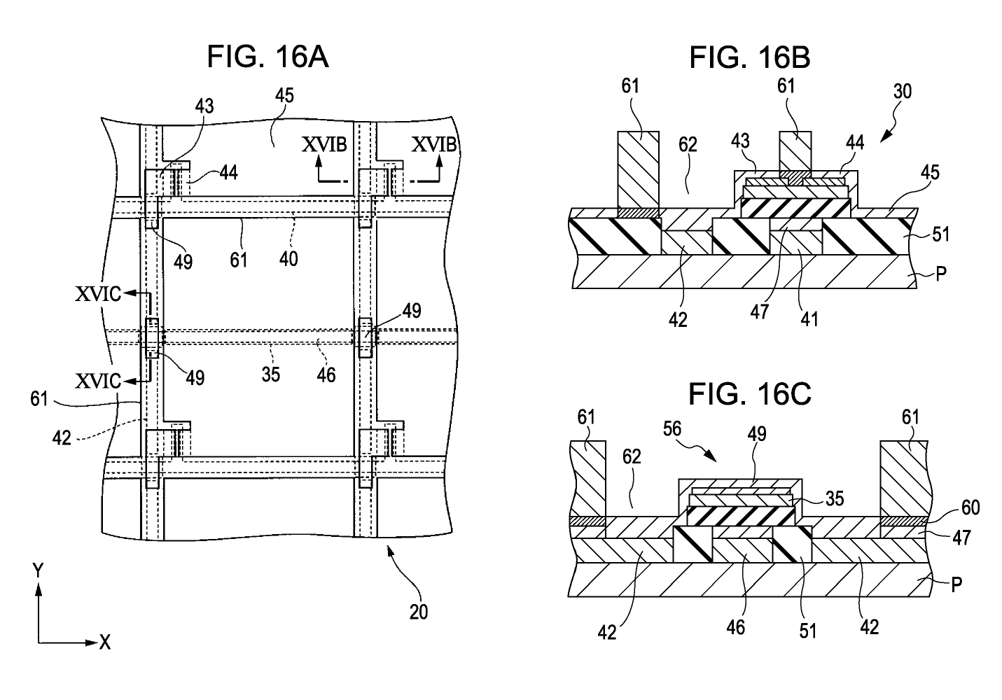

As such, the pixel electrode 45 which is electrically connected to the drain electrode 44 is formed on the substrate P, as shown in FIG. 16.

In the present process, the banks 61 of the boundary portion between electrode 44 and the pixel electrode 45 are removed by laser or the like, in order to electrically connect the drain electrode 44 and the pixel electrode 45. The present process is not limited thereto. For example, if the bank 61 of the boundary portion is previously thinned by half-exposure or the like, the liquid material for pixel electrode can be discharged and disposed so as to be overlapped with the drain electrode 44, even though the banks 61 of the boundary portion are not removed.

Through the above-described processes, it is possible to manufacture the active matrix substrate 20. In the present embodiment, the forming method according to the invention is applied when a conductive film is formed of liquid material. Therefore, a particle sintered film which is electrically stable can be obtained for each conductive film, and a reliable active matrix substrate can be manufactured at low cost.

In the present embodiment, before forming the upper wiring layer (the source electrode 43, the drain electrode 44, and the pixel electrode 45), the surface of the bank 51 serving as a base layer is previously subjected to the liquid-affinity treatment. Therefore, the wettability between the substrate and the liquid material is improved, and a uniform film pattern can be formed.

In the present embodiment, the active matrix substrate 20 is manufactured by the first process of forming the wiring lines with a lattice pattern on the substrate P, the second process of forming the laminate section 35, and the third process of forming the pixel electrode 45 and the like. Therefore, the treatment in which a drying process and photolithographic etching process are combined can be reduced. In other words, since the gate wiring lines 40 and the source wiring lines 42 are formed at the same time, the treatment in which a drying process and photolithographic etching process are combined can be reduced by one time.

In addition, the laminate section 35 (the insulating film 31, the active layer 32, and the contact layer 33) formed on the capacitance line 46 is formed so as not to come in contact with the laminate section 35 formed on the intersection section 56. Therefore, it can be prevented that the electric current flowing in the source wiring lines 42 flows into the laminate section 35 on the capacitance line 46.

In other words, among the layers forming the laminate section 35, the contact layer 33 is a conductive film. Further, on the laminate section 35 (the contact layer 33) on the upper side of the intersection section 56, the conductive layer 49 connecting the source wiring lines 42 is formed. Therefore, the current flowing in the source wiring lines 42 also flows into the contact layer 33. Accordingly, if the laminate section 35 on the capacitance line 46 and the laminate section 35 on the intersection section 56 come in contact with each other, the current flowing in the source wiring lines 42 flows into the laminate section 35 on the capacitance line 46, as described above. Therefore, the active matrix substrate 20 according to the invention can avoid such drawbacks and can exhibit desired performance.

Electro-Optical Device

Next, a liquid crystal display device 100 which is an example of an electro-optical device using the active matrix substrate 20 will be described. FIG. 17A is a plan view illustrating the liquid crystal display device 100, seen from a counter substrate side, and FIG. 17B is a cross-sectional view taken along the line XVII-XVII of FIG. 17A.

In FIGS. 17A and 17B, the liquid crystal display device (electro-optical device) 100 is provided with a TFT array substrate 110 including the active matrix substrate 20 and a counter substrate 120, which are bonded to each other by a sealing material 152 which is a photosetting sealing member. In the region partitioned by the sealing material 152, liquid crystal 150 is filled so as to be held.

In the region inside the formation region of the sealing material 152, a peripheral parting line 153 composed of a light shielding material is formed. In the region outside the sealing material 152, a data line driving circuit 201 and mounting terminals 202 are formed along one side of the TFT array substrate 110. Along two sides adjacent to the one side, scanning line driving circuits 204 are formed. In the remaining side of the TFT array substrate 110, a plurality of wiring lines 205 are provided so as to connect the scanning line driving circuits 204 provided in both sides of an image display region. In at least one corner of the counter substrate 120, an inter-substrate conductive member 206 is disposed so as to electrically connect the TFT array substrate 110 with the counter substrate 120.

Instead of forming the data line driving circuit 201 and the scanning line driving circuit 204 on the TFT array substrate 110, a TAB (tape automated bonding) substrate having a driving LSI mounted thereon and a group of terminals formed on the peripheral portion of the TFT array substrate 110 may be electrically and mechanically connected to each other through an anisotropic conductive film.

In the liquid crystal display device 100, a retardation plate, polarization plate, and the like (not shown) are disposed in a predetermined direction, in accordance with the type of liquid crystal 150 to be used, that is, the operation mode such as a TN (Twisted Nematic) mode, a C-TN method, a VA method, an IPS method and the like or the normally-white mode/normally-black mode. When the liquid crystal display device 100 is constructed as a device for color display, red (R), green (G), and blue (B) color filters and protecting films thereof are formed in the regions of the counter substrate 120 opposite to the respective pixel electrodes (to be described below) of the TFT array substrate 110.

In the liquid crystal display device 100, the active matrix substrate 20 is manufactured by the above-described method. Therefore, it is possible to implement a liquid crystal device which provides high-quality display and has high reliability.

The above-described active matrix substrate can be also applied to other electro-optical devices other than the liquid crystal display device, such as an organic EL (electro-luminescent) display device and the like. The organic EL display device has a structure in which a thin film including a fluorescent inorganic or organic compound is interposed between a cathode and anode. The electrons and holes injected into the thin film are excited to generate exciters (excitons), and the excitons are recombined to emit light. The organic EL display device emits light by using the light emission (fluorescent light/phosphor light) when the excitons are recombined. Among fluorescent materials which are used in the organic EL display element, materials showing respective luminescent colors of red, green, and blue, that is, a light emitting layer forming material and a material forming a hole injecting/electron transporting layer are set to liquid material, and are patterned on the substrate having the TFT 30, thereby forming a self-light-emitting full color EL device. In the scope of the electro-optical device in the invention, such an organic EL device is also included. Moreover, in the organic EL display device, the film pattern forming method of the invention can be applied as a method forming the hole injecting/electron transporting layer forming material and the light-emitting layer forming material.

The active matrix substrate 20 can be applied to a PDP (plasma display panel) or a surface-conduction electron-emitter which uses the electron emission generated by flowing electric currents parallel to a film surface into a thin film having a small area which is formed on a substrate.

Other Substrates for Electronic Apparatus

The conductive film forming method of the invention is not limited to the manufacturing of an electro-optical device (active matrix substrate), but can be applied to the manufacturing of various substrates for an electronic apparatus. For example, the conductive film forming method can be preferably used in a conductive film forming process when a substrate constituting a touch panel (coordinate input device) is manufactured or in a process of forming a conductive film as an antistatic film of various panels.

Hereinafter, a method of manufacturing a substrate for an electronic apparatus using a flexible substrate which is suitable for touch panel application will be described.

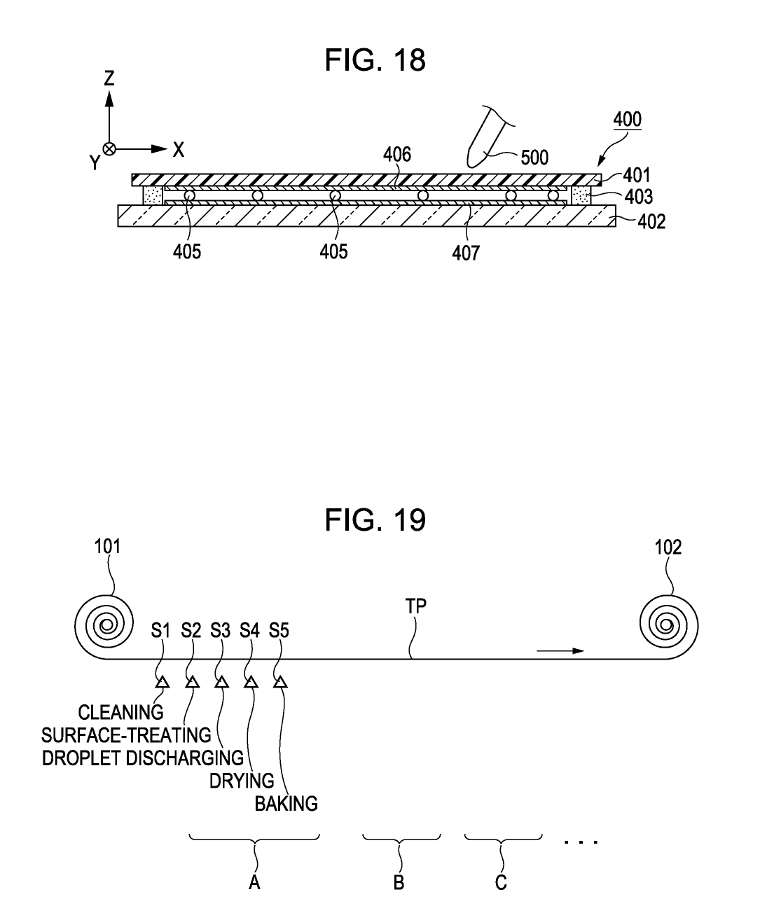

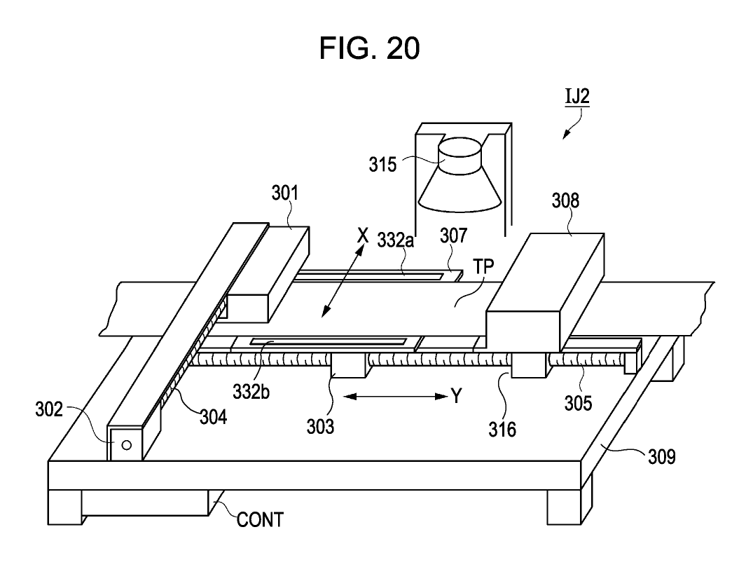

FIG. 18 is a cross-sectional view showing an example of the construction of a touch panel. FIG. 19 is a schematic view showing a conductive film forming device which is used in manufacturing the substrate for an electronic apparatus of the present embodiment. FIG. 20 is a perspective view illustrating a droplet discharge device which is provided with the conductive film forming device shown in FIG. 19.

Touch Panel

A touch panel 400 shown in FIG. 18 is provided with a transparent and flexible upper substrate 401 composed of a resin material and a transparent lower substrate 402 composed of glass, which are bonded to each other through a sealing material 403. The upper substrate 401 and the lower substrate 402 are spaced at a predetermined distance by a plurality of insulating beads (spacers) 405 interposed therebetween. On the respective opposite surfaces of the upper substrate 401 and the lower substrate 402, an upper electrode 406 and lower electrode 407 are formed, which are composed of a transparent conductive material such as ITO.

When the touch panel 400 having such a construction operates, the electrical potential distribution in the X direction of the drawing is formed in the upper electrode 406, and the electrical potential distribution in the Y direction of the drawing is formed in the lower electrode 407. Further, if an indicator 501 such as a finger or pen is caused to slide on the outer surface (the surface in the positive Z direction of the drawing) of the upper substrate 401 which is a flexible substrate in the tough panel 400, the upper substrate 401 of the position where the indicator 500 is abutted on the upper substrate 401 is bent by a pressing force, such that the upper electrode 406 and the lower electrode 407 come in contact and are short-circuited in the pressing position. Accordingly, the coordinate information in the X and Y direction can be extracted from the upper and lower electrodes 406 and 407, and it is possible to obtain plane coordinates (X, Y) of the position pressed by the indicator 500.

Conductive Film Forming Device

A conductive forming device according to present embodiment shown in FIG. 19 is provided with, at least, a first reel 101 around which a tape-shaped substrate TP is wound, a second reel 102 which reels the taped-shaped substrate TP pulled out of the first reel 101, and a droplet discharge device IJ2 which discharges droplets onto a tape-shaped substrate TP.

As the tape-shaped substrate TP, for example, a band-shaped flexible substrate is applied. The tape-shaped substrate TP is constructed of polyimide or the like. The tape-shaped substrate TP has, for example, a width of 105 mm and a length of 200 m. The tape-shaped substrate TP composes a ‘reel-to-reel substrate’ of which both band-shaped end portions are reeled around the first reel 101 and the second reel 102. In other words, the tape-shaped substrate TP pulled out of the first reel 101 is reeled around the second reel 102 so as to continuously travel in the longitudinal direction thereof. On the tape-shaped substrate TP continuously traveling, the droplet discharge device IJ2 discharges liquid material as droplets so as to form a conductive film having a predetermined plan shape. Further, the tape-shaped substrate TP on which the conductive film is formed in such a manner is divided by a predetermined dimension, thereby manufacturing a plurality of upper substrates 401 of the touch panel 400 shown in FIG. 18.

The conductive film forming device of the present embodiment has a plurality of devices which respectively execute a plurality of processes with respect to the reel-to-reel substrate composed of one tape-shaped substrate TP. As the plurality of processes, there are exemplified a cleaning process S1, a surface-treating process S2, a droplet discharging process S3, a drying process S4, and a baking process S5, shown in FIG. 18. Through these processes, it is possible to form a wiring layer, an electrode layer, an insulating layer, and the like on the tape-shaped substrate TP.

In the conductive film forming device, a plurality of substrate formation regions (desired regions) are set by dividing the tape-shaped substrate TP in the longitudinal direction at a predetermined length. Further, the tape-shaped substrate TP is continuously moved to the device of each process, so that the wiring layer, the insulating layer, and the like are consecutively formed on the respective substrate formation region of the tape-shaped substrate TP. In other words, the plurality of processes S1 to S5 are performed on an assembly line, and performed by the plurality of devices at the same time or redundantly in time.

Droplet Discharge Device

The droplet discharge device IJ2 shown in FIG. 20 will be described in detail with reference to the drawing. The droplet discharge device IJ2 shown in FIG. 20 is provided with a mechanism which effectively discharges droplets onto the tape-shaped substrate TP, so that the droplet discharge device IJ2 is capably used in the conductive film forming device shown in FIG. 19. In the droplet discharge device IJ2 shown in FIG. 20, like reference numerals are attached to the same components as those of the droplet discharge device IJ shown in FIG. 1, and the descriptions thereof will be omitted.

In the droplet discharge device IJ2, the X-direction driving shaft 304, the X-direction driving motor 302, the Y-direction guide shaft 305, the Y-direction driving motor 303, and the stage 307 compose a head moving mechanism which relatively moves the droplet discharge head 301 with respect to the tape-shaped substrate TP aligned on the stage 307. The X-direction driving shaft 304 supports the droplet discharge head 301 in the direction (X direction) substantially orthogonal to the longitudinal direction (Y direction) of the tape-shaped substrate TP, and serves as a guide which allows the droplet discharge head 301 to scan in the X direction, when the droplet discharge head 301 discharges droplets.

The droplet discharge head 301 discharges dispersion liquid (liquid material) containing particulate materials from the nozzles (discharge ports), so that the dispersion liquid is disposed at a predetermined distance on the tape-shaped substrate TP. The stage 307 mounts the tape-shaped substrate TP on which dispersion liquid is coated by the droplet discharge device IJ2, and is provided with a mechanism (alignment mechanism) which fixes the tape-shaped substrate TP in a reference position. Moreover, substantially-rectangular regions provided on the stage 307, which are indicated by reference numerals 332a and 332b, are flushing regions for performing the dummy (flushing) operation of the droplet discharge head 301.

The heater 315 is a lamp heater provided with a flash lamp, like the above-described droplet discharge device IJ. The heater 315 heats (dries or bakes) the tape-shaped substrate TP by annealing through the light-irradiation using a flash lamp. In other words, the heater 315 performs the heat-treatment so as to evaporate and remove the dispersion medium included in the liquid material discharged on the tape-shaped substrate TP, so that the particulate materials are sintered to be converted into a conductive film.

According to the droplet discharge device IJ2 of the present embodiment, the droplet discharge head 301 is moved along the X-direction driving shaft 304 and the Y-direction guide shaft 405, so that droplets are disposed in an arbitrary position of a desired region on the tape-shaped substrate TP, which makes it possible to form a pattern of liquid material. After forming a pattern on one desired region, the tape-shaped substrate TP is displaced in the longitudinal direction (Y direction), such that a pattern can be extremely easily formed on another desired region. Here, the desired region can be caused to correspond to one substrate for an electronic apparatus (upper substrate 401). In the present embodiment, the conductive film can be simply and rapidly formed on each desired region (each circuit substrate region) of the tape-shaped substrate TP, which makes it possible to effectively manufacture multiples substrates for an electronic apparatus.

In the conductive film forming device of the present embodiment, it is preferable that the tape-shaped substrate TP is reeled around the second reel 102 so that the surface of the tape-shaped substrate TP where the liquid material is coated by the droplet discharge device IJ2 is directed inside. Preferably, the inner surface of the tape-shaped substrate TP which is wound around the first reel 101 is a surface on which the liquid material is coated by the droplet discharge device IJ2. Then, the tape-shaped substrate TP is reeled by the second reel 102 so that the surface of the tape-shaped substrate TP on which the conductive film is formed is set to the internal side. Therefore, it is possible to maintain the corresponding pattern in a good state. Further, since the bending direction of the tape-shaped substrate TP is identical in both the first reel 101 and the second reel 102, it is possible to reduce a mechanical external force action with respect to the tape-shaped substrate TP and to reduce the deformation of the tape-shaped substrate TP.

In the conductive film forming device of the present embodiment, the droplet discharge device IJ2 may be provided with one or a plurality of droplet discharge heads 301 which can discharge droplets on the front surface and rear surface of the tape-shaped substrate TP at the same time. In such a droplet discharge device IJ2, the surface of the tape-shaped substrate TP is held in a perpendicular state, and the droplet discharge heads 301 are provided so as to be respectively disposed in the front surface side and rear surface side of the tape-shaped substrate TP. Such a construction allows the conductive film to be formed on the front and rear surface of the tape-shaped substrate TP at the same time. In the case of the touch panel 400, the upper electrode 406 on the internal surface side (the lower electrode 402 side) of the upper electrode 401 and the antistatic film on the external surface side of the upper substrate 401 can be formed at the same time. Therefore, according to the present construction, it is possible to remarkably reduce the manufacturing time and manufacturing cost.

Method of Manufacturing Substrate for Electronic Apparatus

The plurality of processes which are performed with respect to the tape-shaped substrate TP as a reel-to-reel substrate will be described specifically. First, the desired region of the tape-shaped substrate TP pulled out of the first reel 101 is subjected to the cleaning process S1 (Step S1). As a specific example of the cleaning process S1, UV (ultra-violet) irradiation onto the tape-shaped substrate TP is exemplified. Further, the tape-shaped substrate TP may be cleaned in a solvent such as water or may be cleaned by using supersonic waves. Furthermore, the tape-shaped substrate TP may be cleaned by plasma-irradiation at normal pressures.

Next, after the cleaning process S1 is carried out, the desired region of the tape-shaped substrate TP is subjected to the surface-treating process S2 in which the liquid-affinity or liquid-repellency is imparted (Step S2). In order to form a conductive film on the tape-shaped substrate TP by using liquid material containing particulate materials in the droplet discharging process of Step S3, it is preferable that the wettability of the surface of the tape-shaped substrate TP with respect to the liquid material containing particulate materials should be controlled. The wettability control can be performed by a surface-treating method in the conductive film forming method which has been described with reference to FIG. 4. In other words, after the surface of the tape-shaped substrate TP is subjected to the liquid-repellency treatment by a self-organizing film forming method or the like, only a portion of the liquid-repellent surface can be subjected to the liquid-affinity treatment.

Next, in the desired region of the tape-shaped substrate TP, which has been subjected to the surface-treating process S2, the liquid-discharge process S3 is performed which is a material coating process in which the liquid material containing particulate materials are discharged and coated (Step S3).

The droplet discharge in the droplet discharge process S3 can be effectively performed by using the droplet discharge device IJ2 shown in FIG. 19. When wiring lines are formed on the tape-shaped substrate TP, the liquid material discharged in the droplet discharging process is liquid containing particulate materials. In the case of the present embodiment, the liquid material is dispersion liquid in which ITO particles are dispersed into a dispersion medium, because a conductive film of the substrate for a touch panel is formed. Further, the droplets of dispersion liquid are discharged from the liquid droplet head so as to be dropped on a region on the substrate in which the conductive film should be formed.

Next, after the droplet discharging process S3 is carried out, the desired region of the tape-shaped substrate TP is subjected to the drying process (Step S4).

The drying process S4 is a hardening process in which the liquid material containing particulate materials, which has been coated in the droplet discharging process S3, is hardened. By repeating Step S3 and Step S4 (Step 2 may be included), it is possible to increase a thickness and to simply form a conductive film with a desired shape and a desired thickness.

As a specific example of the drying process S4, there is a method in which the liquid material coated on the tape-shaped substrate TP is dried so as to be hardened. Specifically, heating treatment using a hot plate, an electric furnace or the like or drying treatment by blowing dry air can be applied. Further, if light irradiation treatment is performed by a flash lamp as used in the previous embodiment, the baking process can be carried out at the same time, and the liquid material coated on the substrate TP can be rapidly converted into a conductive film (ITO film).

Next, the baking process S5 is performed in which the dried film obtained by the drying treatment is baked in the desired region of the tape-shaped substrate TP (Step S5). The baking process S5 is where the dried film, which is coated in the droplet discharge process S3 and is then subjected to the drying process, is baked so as to form a conductive film having a desired sheet resistance. By the baking process S5, the electrical contact between the particles forming the dried film on the tape-shaped substrate TP is secured, while the dried film is converted into a conductive film.

Similar to the embodiment described in FIGS. 2 and 4, the baking process S5 is the light-irradiation treatment process using a flash lamp. The light-irradiation conditions of the flash lamp are as follows: light-irradiation energy ranges from 1 to 50 J/cm² and a light-irradiation time ranges from 1 μm to a few milliseconds. The baking process S5 of the present embodiment is also typically carried out in the air. However, the baking process S5, if necessary, can be carried out in an inert gas atmosphere such as nitrogen, argon, helium or the like.

By the baking process, the dispersion medium included in the dried film is completely removed, and the coating material on the particulate material is also removed, so that the conductive film in which the particulate materials are aggregated so as to come in electric contact is formed on the substrate TP. Even in the conductive film forming device of the present embodiment, it is possible to obtain a conductive film provided with a stable electric characteristic while the sheet resistance hardly changes over time. Even in the conductive film forming device of the present embodiment, the baking process of the dried film is performed by instantly heating the film by using a flash lamp. Therefore, the crystallinity of the particle surface can be recovered by the assistance of light energy, and the necking or adhesion between the particles is stimulated by the light energy. As a result, a stable conductive state between the particles can be formed in the drying/baking process.

In the present embodiment, since a conductive film is formed on the tape-shaped substrate TP composing a reel-to-reel substrate by using the droplet discharge device, it is possible to effectively manufacture a large number of substrates for an electronic apparatus having a conductive film. In other words, according to this embodiment, the desired region of one tape-shaped substrate TP which becomes multiple plate-shaped substrates as a product is aligned in a desired position of the droplet discharge device IJ2, so that a conductive film having a desired plan shape can be performed in the desired region. Accordingly, after a pattern is formed on one desired region by the droplet discharge device IJ2, the tape-shaped substrate TP is displaced with respect to the droplet discharge device, so that a conductive film can be extremely simply formed on another desired region of the tape-shaped substrate TP. In the present embodiment, a conductive film can be simply and rapidly formed on each desired region of the tape-shaped substrate TP composing a reel-to-reel substrate, which makes it possible to effectively manufacture a large number of substrates for an electronic apparatus.

According to the present embodiment, the plurality of processes including a material disposing process are performed until the tape-shaped substrate TP composing a reel-to-reel substrate is pulled out of the first reel 101 and reeled around the second reel 102. Accordingly, reeling one end of the tape-shaped substrate TP around the second reel 102 allows the tape-shaped substrate TP to move from the device executing the cleaning process S1 to the device executing the next surface-treating process S2 and further to the device executing the following process. Therefore, in the present embodiment, a conveying mechanism and alignment mechanism, which moves the tape-shaped substrate TP to the device of each process, can be simplified, which makes it possible to reduce the installation space of a manufacturing device and a manufacturing cost in a mass production.

In the conductive film forming device of the present embodiment and the conductive film forming method using the device, it is preferable that the time required in the respective processes is set to be substantially identical. Then, the respective processes can be synchronously executed in parallel, the manufacture can be more rapidly performed, and utilization efficiency of the device in each process can be improved. In particular, in the conductive film forming device of the present embodiment, the light-irradiation treatment using a flash lamp by which the baking treatment can be carried out in mere a few seconds is used instead of the baking process in which a few hours have been required in the related art. Therefore, it is of great advantage to synchronize the time required in the respective processes, and it is possible to easily improve the efficiency of the conductive film forming process.

Electronic Apparatus

Next, a specific example of an electronic apparatus of the invention will be described.

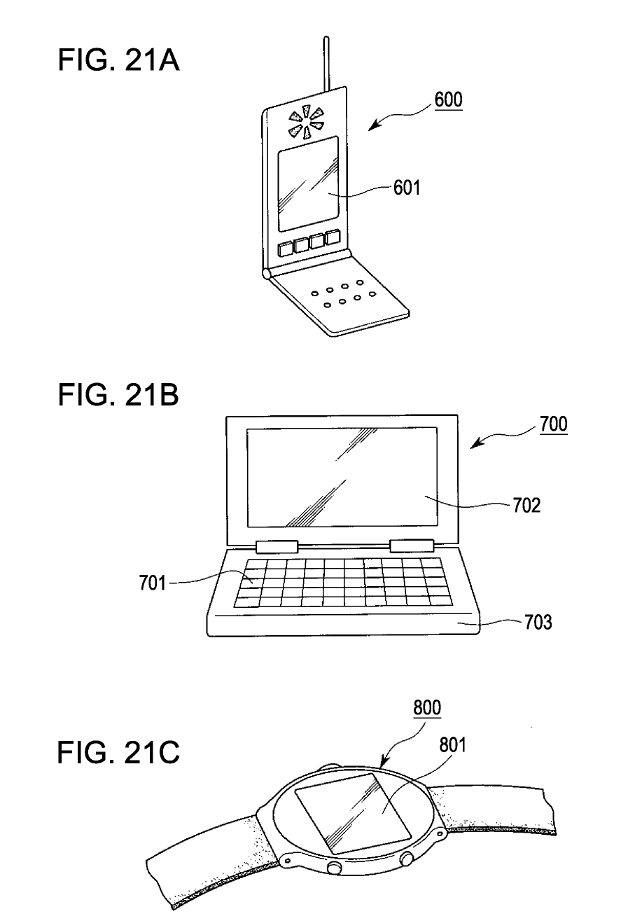

FIG. 21A is a perspective view illustrating an example of a mobile phone. Reference numeral 600 represents a mobile phone main body, and reference numeral 601 represents a display section provided with the liquid crystal display device 100 of the above-described embodiment.

FIG. 21B is a perspective view illustrating an example of a portable information processing device such as a word processor or personal computer. Reference numeral 700 represents an information processing device, reference numeral 701 represents an input section such as a keyboard, reference numeral 703 represents an information processing main body, and reference numeral 702 represents a display section provided with the liquid crystal display device 100 of the embodiment.

FIG. 21C is a perspective view illustrating an example of a watch-type electronic apparatus. Reference numeral 800 represents a watch main body, and reference numeral 801 represents a display section provided with the liquid crystal display device 100 of the embodiment.

The electronic apparatuses shown in FIGS. 21A to 21C are provided with the liquid crystal display device 100 of the embodiment. Since a conductive film excellent in stability of an electrical characteristic is used in an electrode member or the like, the reliability of the electronic apparatuses is improved. Further, the manufacturing method of the embodiment can also be applied to a large-sized liquid crystal panel of a television set, a monitor, or the like.

Moreover, the electronic apparatuses of the present embodiment are provided with the liquid crystal display device 100. However, the electronic apparatuses may be provided with other electro-optical devices such as an organic EL display device, a plasma-type display device, and the like.

While the invention has been described with reference to exemplary embodiments thereof, it will be understood by those skilled in the art that various changes and modifications in form and detail may be made therein without departing from the scope of the invention as defined by the following claims.

What is claimed is:

1. A method of forming a conductive film comprising:
disposing liquid material containing particulate materials on a substrate; and
baking the liquid material on the substrate through light-irradiation using a flash lamp so as to form a conductive film.

2. The method of forming a conductive film according to claim 1,
wherein the particulate materials are particles of a conductive material of which the bulk melting point is higher than 900° C., and of which the melting point in a particle diameter of 10 to 150 nm is higher than 255° C.

3. The method of forming a conductive film according to claim 1,
wherein the particulate materials are particles of a transparent conductive material.

4. The method of forming a conductive film according to claim 3,
wherein the transparent conductive material is at least one metal oxide which is selected from indium tin oxide, tin oxide, oxidized indium, indium zinc oxide, and halogen-containing tin oxide.

5. The method of forming a conductive film according to claim 1,
wherein the particulate material is at least one metallic particulate material which is selected from copper, nickel, manganese, titanium, tantalum, tungsten, and molybdenum.

6. The method of forming a conductive film according to claim 1,
wherein the liquid material is disposed on the substrate by a droplet discharge method using a droplet discharge device.

7. The method of forming a conductive film according to claim 1,
wherein the liquid material is disposed on the substrate by a CAP coating method using a capillary phenomenon.

8. A method of manufacturing an electronic apparatus comprising a conductive film forming process using the forming method according to claim 1.
